(19) United States
(12) Patent Application Publication
(10) Pub. No.: US 2026/0177919 A1
(43) Pub. Date: Jun. 25, 2026

(54) METHOD FOR MANUFACTURING SEMICONDUCTOR SUBSTRATE, AND RESIST UNDERLAYER FILM FORMING COMPOSITION

(71) Applicant: JSR CORPORATION, Tokyo (JP)

(72) Inventors: Kengo HIRASAWA, Tokyo (JP); Ryotaro TANAKA, Tokyo (JP); Yuki OKA, Tokyo (JP); Sho YOSHINAKA, Tokyo (JP)

(73) Assignee: JSR CORPORATION, Tokyo (JP)

(21) Appl. No.: 19/539,222

(22) Filed: Feb. 13, 2026

Related U.S. Application Data
(63) Continuation-in-part of application No. PCT/JP2024/029817, filed on Aug. 22, 2024.

(30) Foreign Application Priority Data
Aug. 25, 2023 (JP) 2023-137458

(51) Int. Cl. G03F 7/09; G03F 7/039; G03F 7/11

(52) U.S. Cl. CPC G03F 7/091; G03F 7/0392; G03F 7/0397; G03F 7/094; G03F 7/11

(57) ABSTRACT

A method for manufacturing a semiconductor substrate includes applying a resist underlayer film forming composition. The composition includes a compound which includes a plurality of groups each represented by —OR^{A}. Each R^{A} is independently a hydrogen atom (amount: x), a monovalent heteroatom-containing group having 1 to 10 carbon atoms (amount: y), or a monovalent organic group having 1 to 10 carbon atoms other than the monovalent heteroatom-containing group (amount: z). The compound satisfies relationships of x+y+z=100, 20≤x≤95, and 5≤y≤80. The compound is a polymer including a repeating unit represented by formula (1), an aromatic ring-containing compound that has a molecular weight of 750 or more and 3000 or less and includes —OR^{A}, or a combination thereof. At least one selected from the group consisting of Ar¹, R⁰ and R¹ comprises —OR^{A}.

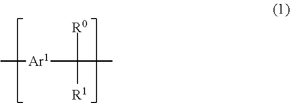

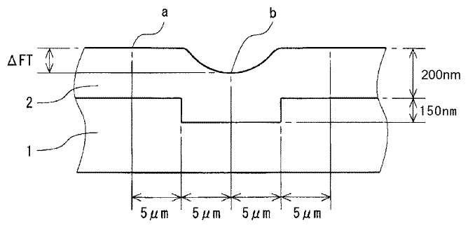

### CROSS-REFERENCE TO RELATED APPLICATIONS

The present application is a continuation-in-part application of International Patent Application No. PCT/JP2024/029817 filed Aug. 22, 2024, which claims priority to Japanese Patent Application No. 2023-137458 filed Aug. 25, 2023. The contents of these applications are incorporated herein by reference in their entirety.

### BACKGROUND OF THE DISCLOSURE

### Technical Field

The present disclosure relates to a method for manufacturing a semiconductor substrate and a resist underlayer film forming composition.

### Background Art

A semiconductor device is produced using, for example, a multilayer resist process in which a resist pattern is formed by exposing and developing a resist film laminated on a substrate with a resist underlayer film, such as an organic underlayer film or a silicon-containing film, being interposed between them. In this process, the resist underlayer film is etched using this resist pattern as a mask, and the substrate is further etched using the obtained resist underlayer film pattern as a mask so that a desired pattern is formed on the semiconductor substrate.

In recent years, highly enhanced integration of semiconductor devices has further advanced, and exposure light to be used tends to have a shorter wavelength, as from a KrF excimer laser beam (248 nm) or an ArF excimer laser beam (193 nm) to an extreme ultraviolet ray (13.5 nm; hereinafter also referred to as “EUV”). Various studies have been conducted on compositions for resist underlayer film formation in such EUV exposure (see WO 2021/157551A).

Compositions for forming a resist underlayer film are required to have pattern rectangularity of securing rectangularity of a resist pattern by inhibiting trailing of a pattern at a bottom part of a resist film.

### SUMMARY

According to an aspect of the present disclosure, a method for manufacturing a semiconductor substrate includes: applying a resist underlayer film forming composition directly or indirectly to a substrate to form a resist underlayer film; applying a composition for forming a resist film directly or indirectly to the resist underlayer film to form a resist film; exposing the resist film to light; and developing the exposed resist film. The resist underlayer film forming composition includes: a compound (hereinafter also referred to as “compound [A]”); and a solvent (hereinafter also referred to as “solvent [B]”). The compound includes a plurality of groups each represented by —OR^{A}, wherein each R^{A} is independently a hydrogen atom, a monovalent heteroatom-containing group having 1 to 10 carbon atoms, or a monovalent organic group having 1 to 10 carbon atoms other than the monovalent heteroatom-containing group having 1 to 10 carbon atoms. In the plurality of R^{A}'s, when a proportion of hydrogen atoms is denoted by x, a proportion of monovalent heteroatom-containing groups having 1 to 10 carbon atoms is denoted by y, and a proportion of monovalent organic groups having 1 to 10 carbon atoms is denoted by z, the compound satisfies relationships of x+y+z=100, 20≤x≤95, and 5≤y≤80. The compound is a polymer including a repeating unit represented by formula (1) (hereinafter, also referred to as “polymer [A1]”), an aromatic ring-containing compound that has a molecular weight of 750 or more and 3000 or less and includes —OR^{A} (hereinafter, also referred to as “aromatic ring-containing compound [A2]”), or a combination thereof.

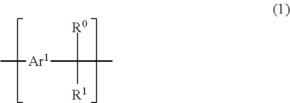

In the formula (1), Ar¹ is a divalent group including an aromatic ring having 5 to 40 ring members; R⁰ is a hydrogen atom or a monovalent organic group having 1 to 40 carbon atoms; R¹ is a monovalent organic group having 1 to 40 carbon atoms; at least one selected from the group consisting of Ar¹, R⁰ and R¹ comprises —OR^{A}.

According to another aspect of the present disclosure, a resist underlayer film forming composition includes: a compound; and a solvent. The compound includes a plurality of groups each represented by —OR^{A}, wherein each R^{A} is independently a hydrogen atom, a monovalent heteroatom-containing group having 1 to 10 carbon atoms, or a monovalent organic group having 1 to 10 carbon atoms other than the monovalent heteroatom-containing group having 1 to 10 carbon atoms. In the plurality of R^{A}'s, when a proportion of hydrogen atoms is denoted by x, a proportion of monovalent heteroatom-containing groups having 1 to 10 carbon atoms is denoted by y, and a proportion of monovalent organic groups having 1 to 10 carbon atoms is denoted by z, the compound satisfies relationships of x+y+z=100, 20≤x≤95, and 5≤y≤80. The compound is a polymer including a repeating unit represented by formula (1), an aromatic ring-containing compound that has a molecular weight of 750 or more and 3000 or less and includes —OR^{A}, or a combination thereof.

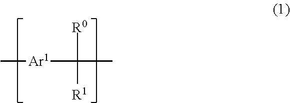

In the formula (1), Ar¹ is a divalent group including an aromatic ring having 5 to 40 ring members; R⁰ is a hydrogen atom or a monovalent organic group having 1 to 40 carbon atoms; R¹ is a monovalent organic group having 1 to 40 carbon atoms; at least one selected from the group consisting of Ar¹, R⁰ and R¹ comprises —OR^{A}.

### BRIEF DESCRIPTION OF THE DRAWING

The FIGURE is a schematic cross-sectional view of a silicon substrate with a resist underlayer film for explaining a method for evaluating flatness.

### DETAILED DESCRIPTION OF THE EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

According to the method for manufacturing a semiconductor substrate, since a resist underlayer film excellent in pattern rectangularity is formed, a well patterned semiconductor substrate can be obtained. According to the composition for forming a resist underlayer film, it is possible to form a resist underlayer film excellent in pattern rectangularity. Furthermore, according to the method for manufacturing a semiconductor substrate, it is possible to form a resist underlayer film excellent in embeddability with which a pattern of a substrate can be sufficiently embedded and also in flatness of the film after the pattern is embedded. The composition for forming a resist underlayer film can form a resist underlayer film excellent also in embeddability and flatness. Therefore, they can suitably be used for, for example, manufacturing semiconductor devices expected to be further microfabricated in the future.

Hereinafter, a method for manufacturing a semiconductor substrate and a composition for forming a resist underlayer film according to each embodiment of the present disclosure will be described in detail. Combinations of suitable modes in embodiments are also preferred.

### <<Method for Manufacturing Semiconductor Substrate>>

The method for manufacturing a semiconductor substrate includes applying a composition for forming a resist underlayer film directly or indirectly to a substrate (hereinafter also referred to as “application step (I)”); applying a composition for forming a resist film directly or indirectly to the resist underlayer film formed by applying the composition for forming a resist underlayer film (hereinafter also referred to as “application step (II)”); exposing the resist film formed by applying the composition for forming a resist film to extreme ultraviolet rays (hereinafter also referred to as “exposing step”); and developing at least the exposed resist film (hereinafter also referred to as “developing step”).

The method for manufacturing a semiconductor substrate may further include, as necessary, forming a silicon-containing film directly or indirectly on the substrate (hereinafter also referred to as “silicon-containing film forming step”) before the application step (I).

First, a composition for forming a resist underlayer film to be used in the method for manufacturing a semiconductor substrate is described. After that, each step in the case of including the silicon-containing film forming step, which is an optional step, will be described.

### <<Composition for Forming Resist Underlayer Film>>

The composition for forming a resist underlayer film (hereinafter also simply referred to as “composition”) includes a compound [A] and a solvent [B]. The composition may contain any optional component as long as the effect of the present disclosure is not impaired.

Each component contained in the composition will be described below.

### <Compound [A]>

The compound [A] has —OR^{A}. The compound [A] is a polymer [A1], an aromatic ring-containing compound [A2](different from compounds corresponding to the polymer [A1]), or a combination thereof. Therefore, the polymer [A1] may have —OR^{A}, the aromatic ring-containing compound [A2] may have —OR^{A}, or both the polymer [A1] and the aromatic ring-containing compound [A2] may have —OR^{A}. Each of the polymer [A1] and the aromatic ring-containing compound [A2] may be used singly or in combination of two or more kinds thereof. Details of —OR^{A} will be described in the sections of polymer [A1] and aromatic ring-containing compound [A2].

### (Polymer [A1])

The polymer [A1] as the compound [A] is a polymer having a repeating unit represented by formula (1). The polymer [A1] may have two or more kinds of repeating units represented by formula (1).

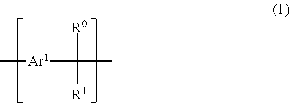

(In the formula (1), Ar¹ is a divalent group having an aromatic ring having 5 to 40 ring atoms. R⁰ is a hydrogen atom or a monovalent organic group having 1 to 40 carbon atoms. R¹ is a monovalent organic group having 1 to 40 carbon atoms. At least one selected from the group consisting of Ar¹, R⁰ and R¹ has —OR^{A}.)

In the formula (1), examples of the aromatic ring having 5 to 40 ring atoms in Ar¹ include aromatic hydrocarbon rings such as a benzene ring, a naphthalene ring, an anthracene ring, a phenalene ring, a phenanthrene ring, a pyrene ring, a fluorene ring, a perylene ring, and a coronene ring; aromatic heterocycles such as a furan ring, a pyrrole ring, a thiophene ring, a phosphole ring, a pyrazole ring, an oxazole ring, an isoxazole ring, a thiazole ring, a pyridine ring, a pyrazine ring, a pyrimidine ring, a pyridazine ring, and a triazine group, or combinations thereof. The aromatic ring of the Ar¹ is preferably at least one aromatic hydrocarbon ring selected from the group consisting of a benzene ring, a naphthalene ring, an anthracene ring, a phenalene ring, a phenanthrene ring, a pyrene ring, a fluorene ring and a perylene ring.

In the present specification, the term “ring members” refers to the number of atoms constituting the ring. For example, a biphenyl ring has 12 ring members, a naphthalene ring has 10 ring members, and a fluorene ring has 13 ring members. The term “polycyclic condensed aromatic ring” refers to a polycyclic aromatic hydrocarbon ring composed of a plurality of aromatic rings sharing a side (a bond between two adjacent atoms).

In the formula (1), suitable examples of the divalent group having an aromatic ring having 5 to 40 ring members represented by Ar¹ include a group obtained by removing two hydrogen atoms from the aromatic ring having 5 to 40 ring members in Ar¹ or a combination of the aromatic ring and a chain structure. In a case where aromatic rings are combined, the aromatic rings may be bonded to each other via a single bond in addition to a condensed ring structure.

As the chain structure, a group obtained by removing two hydrogen atoms from a chain hydrocarbon having 1 to 20 carbon atoms can be suitably employed. Examples of the chain hydrocarbon having 1 to 20 carbon atoms include alkanes having 1 to 20 carbon atoms, such as methane, ethane, propane, butane, hexane, and octane. These may be either linear or branched. Among these, a linear or branched alkane having 1 to 8 carbon atoms is preferred.

In the formula (1), examples of the monovalent organic group having 1 to 40 carbon atoms represented by R⁰ and R¹ include a monovalent hydrocarbon group having 1 to 20 carbon atoms, a group containing a divalent heteroatom-containing linking group between two carbon atoms of this hydrocarbon group or at the end of the hydrocarbon group, a group obtained by substituting some or all of the hydrogen atoms of the hydrocarbon group with a monovalent heteroatom-containing substituent, and a combination thereof.

Examples of the monovalent hydrocarbon group having 1 to 20 carbon atoms include a monovalent chain hydrocarbon group having 1 to 20 carbon atoms, a monovalent alicyclic hydrocarbon group having 3 to 20 carbon atoms, a monovalent aromatic hydrocarbon group having 6 to 20 carbon atoms, and a combination thereof.

Examples of the monovalent chain hydrocarbon group having 1 to 20 carbon atoms include alkyl groups such as a methyl group, an ethyl group, a n-propyl group, an i-propyl group, a n-butyl group, a sec-butyl group, a tert-butyl group; alkenyl groups such as an ethenyl group, a propenyl group and a butenyl group; and alkynyl groups such as an ethynyl group, a propynyl group and a butynyl group.

Examples of the monovalent alicyclic hydrocarbon group having 3 to 20 carbon atoms include cycloalkyl groups such as a cyclopropyl group, a cyclobutyl group, a cyclopentyl group, and a cyclohexyl group; cycloalkenyl groups such as a cyclopropenyl group, a cyclopentenyl group, and a cyclohexenyl group; bridged cyclic saturated hydrocarbon groups such as a norbornyl group, an adamantyl group, and a tricyclodecyl group; and bridged cyclic unsaturated hydrocarbon groups such as a norbornenyl group and a tricyclodecenyl group.

Examples of the monovalent aromatic hydrocarbon group having 6 to 20 carbon atoms include a phenyl group, a tolyl group, a naphthyl group, an anthracenyl group, and a pyrenyl group.

Examples of heteroatoms that constitute the divalent heteroatom-containing linking group or the monovalent heteroatom-containing substituent include an oxygen atom, a nitrogen atom, a sulfur atom, a phosphorus atom, a silicon atom, and halogen atoms. Examples of the halogen atoms include a fluorine atom, a chlorine atom, a bromine atom, and an iodine atom.

Examples of the divalent heteroatom-containing linking group include —CO—, —CS—, —NH—, —O—, —S—, —SO—, —SO₂—, or groups obtained by combining them.

Examples of the monovalent heteroatom-containing substituent include a hydroxy group, a sulfanyl group, a cyano group, a nitro group, and halogen atoms.

R⁰ is preferably a hydrogen atom.

R¹ preferably has an aromatic ring having 5 to 40 ring members. As the aromatic ring having 5 to 40 ring members in R¹, an aromatic ring having 5 to 40 ring members in Ar¹ can be suitably employed.

In the formula (1), at least one selected from the group consisting of Ar¹, R⁰, and R¹ has —OR^{A}. It is preferable that at least one of Ar¹ and R¹ has —OR^{A}. —OR^{A} is bonded to a carbon atom constituting at least one selected from the group consisting of Ar¹, R⁰, and R¹. R^{A} is any of a hydrogen atom, a monovalent heteroatom-containing group having 1 to 10 carbon atoms, or a monovalent organic group having 1 to 10 carbon atoms (different from the monovalent heteroatom-containing group having 1 to 10 carbon atoms) (hereinafter also referred to as “organic group (A)”). Where among the structures constituting the R^{A}, a proportion of hydrogen atoms is denoted by x, a proportion of monovalent heteroatom-containing groups having 1 to 10 carbon atoms is denoted by y, and a proportion of monovalent organic groups having 1 to 10 carbon atoms is denoted by z, the compound satisfies relationships of x+y+z=100, 20≤x≤95, and 5≤y≤80 in the whole compound.

As the monovalent heteroatom-containing group having 1 to 10 carbon atoms represented by R^{A}, among the monovalent organic groups having 1 to 40 carbon atoms represented by R⁰ and R¹, groups corresponding to 1 to 10 carbon atoms and having the divalent heteroatom-containing linking group or the monovalent heteroatom-containing substituent can be suitably employed.

The number of the carbon atoms in the heteroatom-containing group is preferably 1 to 8, more preferably 1 to 6, and still more preferably 1 to 4.

The heteroatom-containing group preferably has at least one selected from the group consisting of —O—, —CO—, —S—, —SO₂—, —NR′— wherein R′ is a monovalent organic group, —NO₂, and —CN. In particular, the heteroatom-containing group more preferably has at least one oxygen atom.

Examples of the heteroatom-containing group include structures represented by formulas (α-1) to (α-12), (β-1) to (β-8), and (γ-1) to (γ-8). It is noted that in the formula, * represents a bond to an oxygen atom.

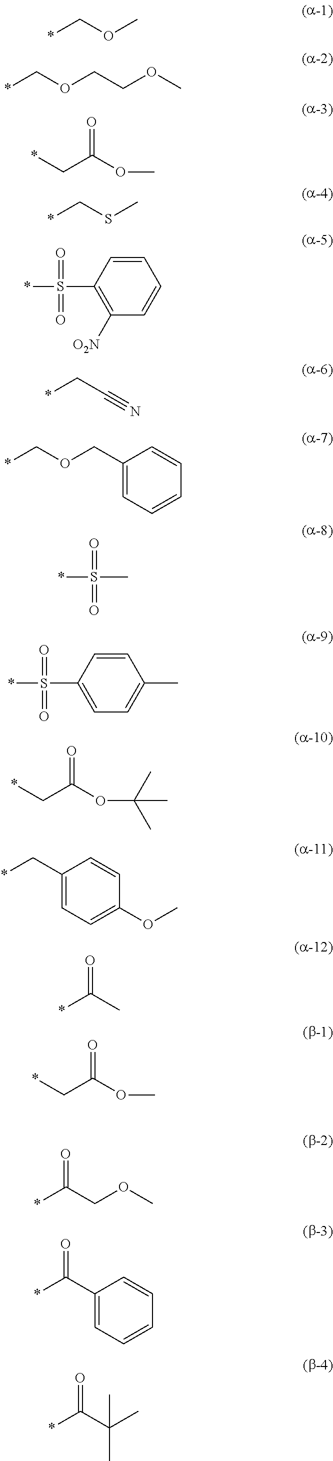

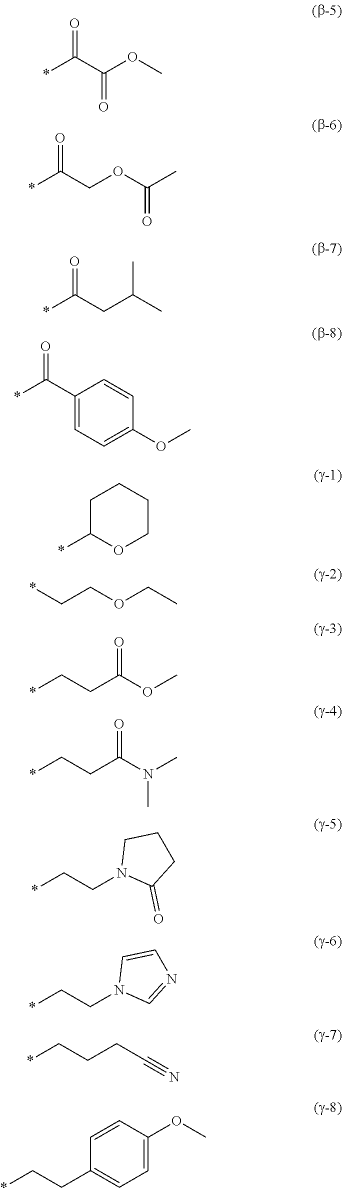

As the organic group (A) represented by R^{A}, groups corresponding to 1 to 10 carbon atoms among the monovalent organic groups having 1 to 40 carbon atoms represented by R⁰ and R¹ can be suitably employed. In particular, as the organic group (A) represented by R^{A}, hydrocarbon groups having 1 to 10 carbon atoms are preferable, chain hydrocarbon groups having 1 to 8 carbon atoms are more preferable, and unsaturated chain hydrocarbon groups having 2 to 6 carbon atoms are still more preferable.

Among the structures constituting R^{A}, the proportion x of hydrogen atoms satisfies a relationship of 20≤x≤95. The lower limit of the proportion x is preferably 30, more preferably 40, still more preferably 50, and particularly preferably 60. The upper limit of the proportion x is preferably 90, more preferably 85, still more preferably 80, and particularly preferably 75.

Among the structures constituting R^{A}, the proportion y of monovalent heteroatom-containing groups having 1 to 10 carbon atoms satisfies the relationship of 5≤y≤80. The lower limit of the proportion y is preferably 10, more preferably 15, still more preferably 20, and particularly preferably 25. The upper limit of the proportion y is preferably 80, more preferably 70, still more preferably 60, and particularly preferably 50.

Among the structures constituting R^{A}, the proportion z of the organic group (A) preferably satisfies 0≤z≤50. When the compound [A] has an organic group (A) as R^{A}, the lower limit of the proportion z is preferably 1, more preferably 3, and still more preferably 5. The upper limit of the proportion z is preferably 40, more preferably 35, and still more preferably 30.

Examples of the repeating unit represented by the formula (1) include repeating units represented by formulas (1-1) to (1-22).

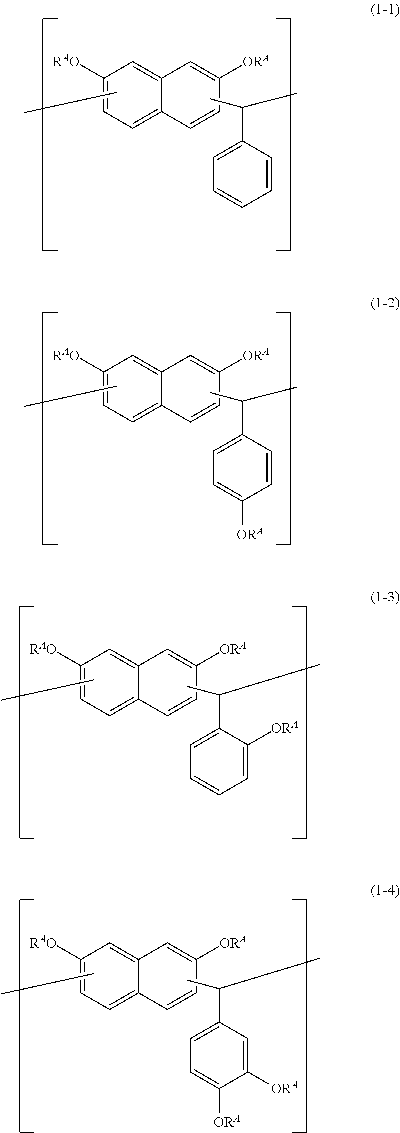

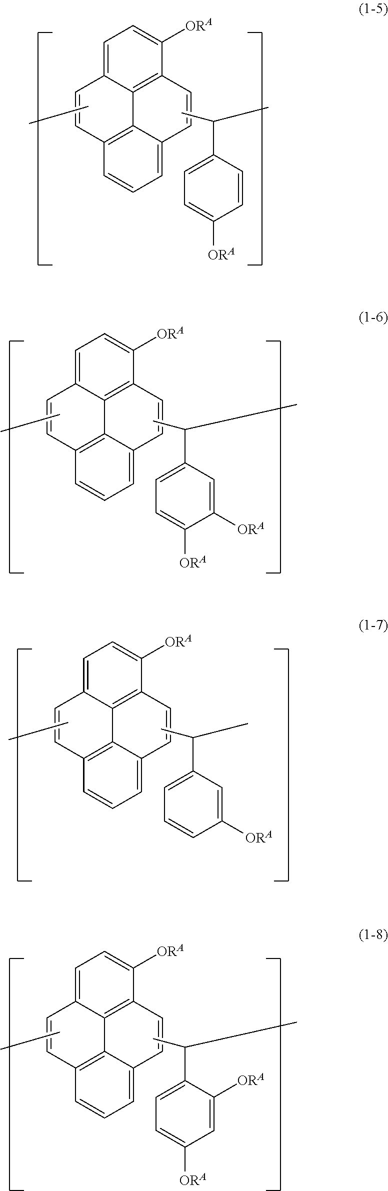

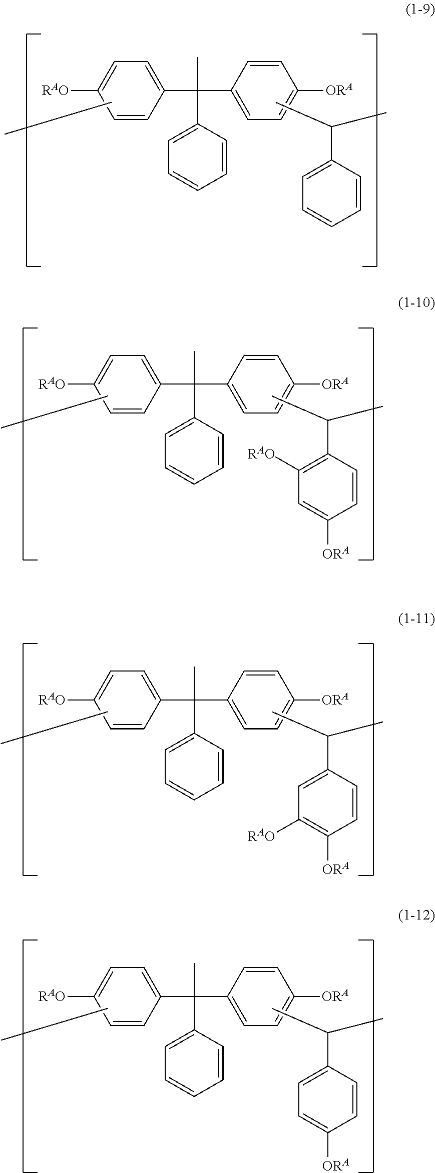

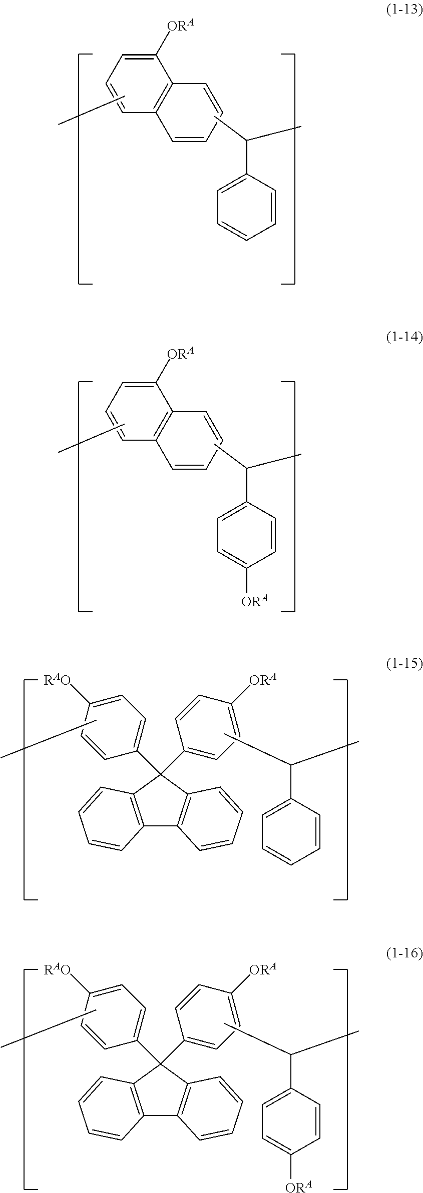

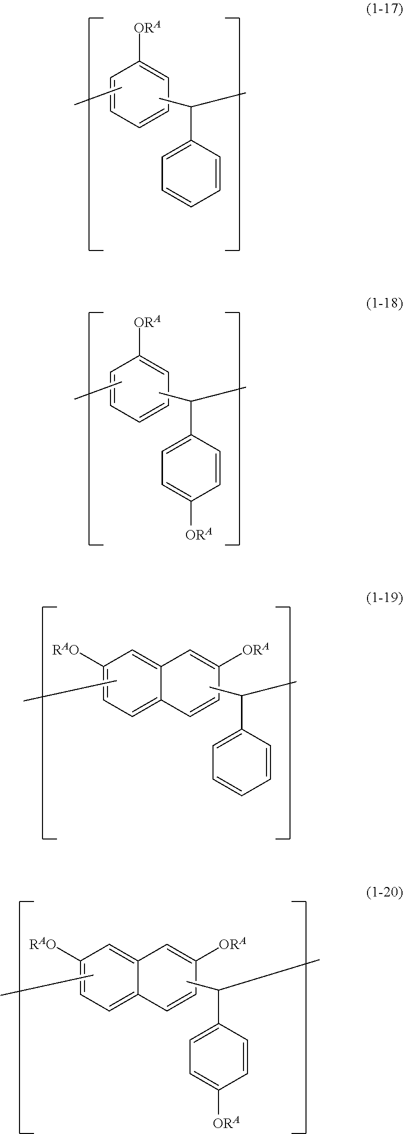

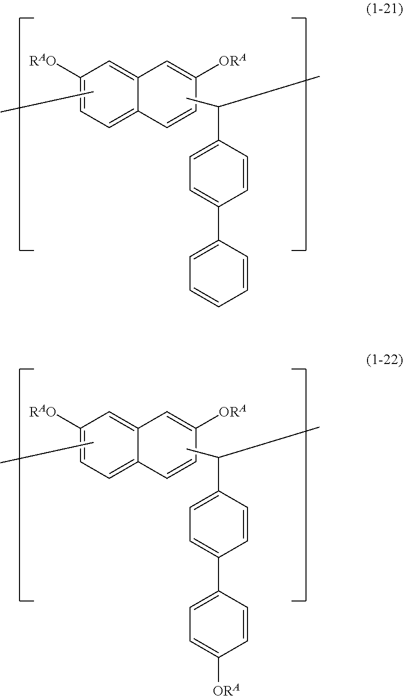

In the above formula, R^{A} is as described above.

The lower limit of the weight average molecular weight of the polymer [A1] is preferably 1000, more preferably 1500, and still more preferably 2000. The upper limit of the molecular weight is preferably 10000, more preferably 8000, and still more preferably 6000. The weight average molecular weight is measured as described in Examples.

### (Method for Manufacturing Polymer [A1])

In the manufacture of the polymer [A1], typically, a precursor polymer is first produced by acid addition condensation of an aromatic ring compound as a precursor having a phenolic hydroxy group that affords Ar¹ in the formula (1) and an aldehyde derivative as a precursor to afford R⁰ and R¹ in the formula (1). The aldehyde derivative may have a phenolic hydroxy group. An acid catalyst is not particularly limited, and publicly known inorganic acids and organic acids can be used.

Next, the phenolic hydroxy group is modified with a modifier, and —OR^{A} is thereby introduced into the polymer [A1]. When a monovalent heteroatom-containing group having 1 to 10 carbon atoms is introduced as R^{A}, specifically, a polymer [A1] in which —OR^{A} is introduced can be produced by a nucleophilic reaction of a halide, an acid anhydride or an acid halide corresponding to the R^{A} as the modifier with a phenolic hydroxy group, or by an addition reaction of a phenolic hydroxy group to a carbon-carbon double bond-containing compound corresponding to the R^{A} as the modifier. The modification rate of the phenolic hydroxy group with the modifier can be controlled by adjusting the number of moles of the modifier based on the number of moles of the phenolic hydroxy group.

Examples of the halide corresponding to the R^{A} include compounds in which a halogen atom is bonded to the site indicated by * in the above formulas (α-1) to (α-12). Examples of the acid anhydride or acid halide corresponding to the R^{A} include compounds in which an acyloxy group or a halogen atom is bonded to the site indicated by * in the formulas (β-1) to (β-8). Examples of the carbon-carbon double bond-containing compound corresponding to the R^{A} include compounds in which a carbon-carbon double bond is formed between the α-position carbon and the β-position carbon with respect to * in the above formulas (γ-1) to (γ-8).

The nucleophilic reaction can be conducted under basic conditions or in the presence of a base. The addition reaction can be conducted in the presence of an acid catalyst. After the reaction, the polymer [A1] can be obtained through separation, purification, drying, and the like. As the reaction solvent, the solvent [B] described later can be suitably employed.

### (Aromatic Ring-Containing Compound [A2])

The aromatic ring-containing compound [A2] is not particularly limited as long as it is a compound having —OR^{A} and a molecular weight of 750 or more and 3000 or less (however, excluding compounds corresponding to the polymer [A1]). The lower limit of the molecular weight of the aromatic ring-containing compound [A2] is preferably 750, more preferably 950, still more preferably 1,050. The upper limit of the molecular weight is preferably 3000, more preferably 2500, still more preferably 2000.

The aromatic ring-containing compound [A2] is preferably a compound represented by formula (3).

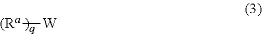

(In the formula (3),

W is a q-valent group containing a substituted or unsubstituted aromatic ring having 5 to 60 ring members,

R^{a} is a monovalent group containing an aromatic ring having 5 to 40 ring members,

q is an integer from 1 to 10, when q is 2 or more, a plurality of R^{a}s are the same as or different from each other, and

at least one of W or one R^{a} or a plurality of R^{a}s has —OR^{A}).

In the formula (3), it is preferred that one R^{a} or a plurality of R^{a}s have —OR^{A}, it is more preferred that at least one of a plurality of R^{a}s has —OR^{A}, and it is still more preferred that all of a plurality of R^{a}s have —OR^{A}.

As the aromatic ring having 5 to 60 ring members in W, an aromatic ring obtained by extending the aromatic ring having 5 to 40 ring members in Ar¹ of the formula (1) to an aromatic ring having 60 ring members can be suitably adopted. Examples of the q-valent group represented by W and containing a substituted or unsubstituted aromatic ring having 5 to 60 ring members include a group in which q hydrogen atoms are removed from the aromatic ring having 5 to 60 ring members.

When W has a substituent, examples of the substituent include monovalent chain hydrocarbon groups having 1 to 10 carbon atoms; halogen atoms such as a fluorine atom, a chlorine atom, a bromine atom, and an iodine atom; alkoxy groups such as a methoxy group, an ethoxy group, and a propoxy group; aryloxy groups such as a phenoxy group and a naphthyloxy group; alkoxycarbonyl groups such as a methoxycarbonyl group and an ethoxycarbonyl group; alkoxycarbonyloxy groups such as a methoxycarbonyloxy group and an ethoxycarbonyloxy group; acyl groups such as a formyl group, an acetyl group, a propionyl group, and a butyryl group; a cyano group, a nitro group, and a hydroxy group.

The aromatic ring of W is preferably at least one aromatic hydrocarbon ring selected from the group consisting of a benzene ring, a naphthalene ring, an anthracene ring, a phenalene ring, a phenanthrene ring, a pyrene ring, a fluorene ring, a perylene ring, and a coronene ring.

In a case where W has —OR^{A}, it is preferred that at least one hydrogen atom of the aromatic ring in W is substituted with —OR^{A}.

As the aromatic ring having 5 to 40 ring members in R^{a}, an aromatic ring having 5 to 40 ring members in Ar¹ of the formula (1) can be suitably adopted. Examples of the monovalent group containing an aromatic ring having 5 to 40 ring members, represented by R^{a}, include a group in which one hydrogen atom is removed from the aromatic ring having 5 to 40 ring members. The aromatic ring of R^{a} is preferably at least one aromatic hydrocarbon ring selected from the group consisting of a benzene ring, a naphthalene ring, an anthracene ring, a phenalene ring, a phenanthrene ring, a pyrene ring, a fluorene ring, a perylene ring, and a coronene ring. When R^{a} has a substituent, a substituent which the W can have can be suitably employed as the substituent of R^{a}.

R^{a} is preferably a group represented by formula (3-1) or (3-2).

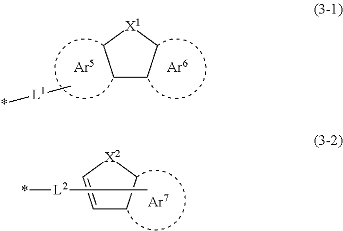

(In the formulas (3-1) and (3-2), X¹ and X² are each independently a group represented by formula (i), (ii), (iii) or (iv), Ar⁵, Ar⁶ and Ar⁷ are each independently a substituted or unsubstituted aromatic ring having 6 to 20 ring members that forms a condensed ring structure together with two adjacent carbon atoms in the formulas (3-1) and (3-2), L¹ and L² are each independently a single bond or a divalent organic group having an aromatic ring, and * is a bond with a carbon atom in W of the formula (3)).

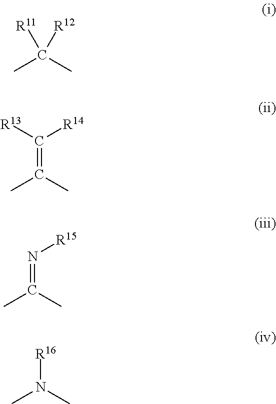

(In the formula (i), R¹¹ and R¹² are each independently a hydrogen atom or a monovalent organic group having 1 to 20 carbon atoms, and at least one of R¹¹ or R¹² has —OR^{A},

in the formula (ii), R¹³ is a hydrogen atom or a monovalent organic group having 1 to 20 carbon atoms, R¹⁴ is a monovalent organic group having 1 to 20 carbon atoms, and at least one of R¹³ or R¹⁴ has —OR^{A},

in the formula (iii), R¹⁵ is a monovalent organic group having 1 to 20 carbon atoms and having —OR^{A}, and in the formula (iv), R¹⁶ is a monovalent organic group having 1 to 20 carbon atoms and having a hydrogen atom or —OR^{A}).

In the formulas (3-1) and (3-2), Ar⁵, Ar⁶ and Ar⁷ (hereinafter, sometimes referred to as “Ar⁵ to Ar⁷”) are each independently a substituted or unsubstituted aromatic ring having 6 to 20 ring members that forms a condensed ring structure together with two adjacent carbon atoms in the formulas (3-1) and (3-2). As the aromatic ring having 6 to 20 ring members in Ar⁵ to Ar⁷, aromatic rings corresponding to 6 to 20 ring members among the aromatic rings having 5 to 40 ring members in Ar¹ of the formula (1) can be suitably adopted.

When Ar⁵ to Ar⁷ have substituents, a substituent which the W can have can be suitably employed as the substituents of Ar⁵ to Ar⁷.

Examples of the monovalent organic group having 1 to 20 carbon atoms represented by R¹¹, R¹², R¹³, R¹⁴, R¹⁵, and R¹⁶ (hereinafter, sometimes referred to as “R¹¹ to R¹⁶”) in the formulas (i), (ii), (iii), and (iv) include a group corresponding to 1 to 20 carbon atoms among the monovalent organic groups having 1 to 40 carbon atoms, represented by R⁵ and R¹ of the formula (1).

It is preferred that at least one of R ¹¹ or R¹² in the formula (i), at least one of R¹³ or R¹⁴ in the formula (ii), R¹⁵ in the formula (iii), and R¹⁶ in the formula (iv) each have an aromatic ring having 5 to 40 ring members. As the aromatic ring having 5 to 40 ring members, the aromatic rings having 5 to 40 ring members in Ar¹ of the formula (1) can be suitably adopted. In this case, it is preferred that at least one hydrogen atom of the aromatic ring is substituted with —OR^{A}. The number of —OR^{A} on the aromatic ring is preferably an integer from 1 to 4, more preferably an integer from 1 to 3, still more preferably 1 or 2.

Suitable examples of the divalent organic group having an aromatic ring in L¹ and L² in the formulas (3-1) and (3-2) include a substituted or unsubstituted group in which two hydrogen atoms are removed from an aromatic ring having 5 to 40 ring members in Ar¹ of the formula (1) (hereinafter also referred to as “group (β)”). The divalent organic group having an aromatic ring represented by L¹ and L² may be a group formed by combining the group (β) with a group obtained by removing one hydrogen atom from a monovalent organic group having 1 to 20 carbon atoms, represented by R¹¹ to R¹⁶. As the divalent organic group having an aromatic ring, represented by L¹ and L², a substituted or unsubstituted arenediyl group having 6 to 12 ring members, a substituted or unsubstituted alkenediyl group having 2 to 10 carbon atoms, an alkynediyl group having 2 to 10 carbon atoms, or a combination thereof are preferred, a benzenediyl group, a naphthalenediyl group, an ethylenediyl group, an ethynediyl group, or a combination thereof is more preferred, and a benzenediyl group or a combination of a benzenediyl group with an ethynediyl group is still more preferred.

In the formulas (3-1) and (3-2), L¹ and L² are preferably single bonds.

Among the structures constituting the R^{A}, the proportion x of hydrogen atoms, the proportion y of monovalent heteroatom-containing groups having 1 to 10 carbon atoms, and the proportion z of organic groups (A) can take the same values as in the case of the polymer [A1].

Examples of the aromatic ring-containing compound [A2] include compounds represented by formulas (3-1) to (3-8).

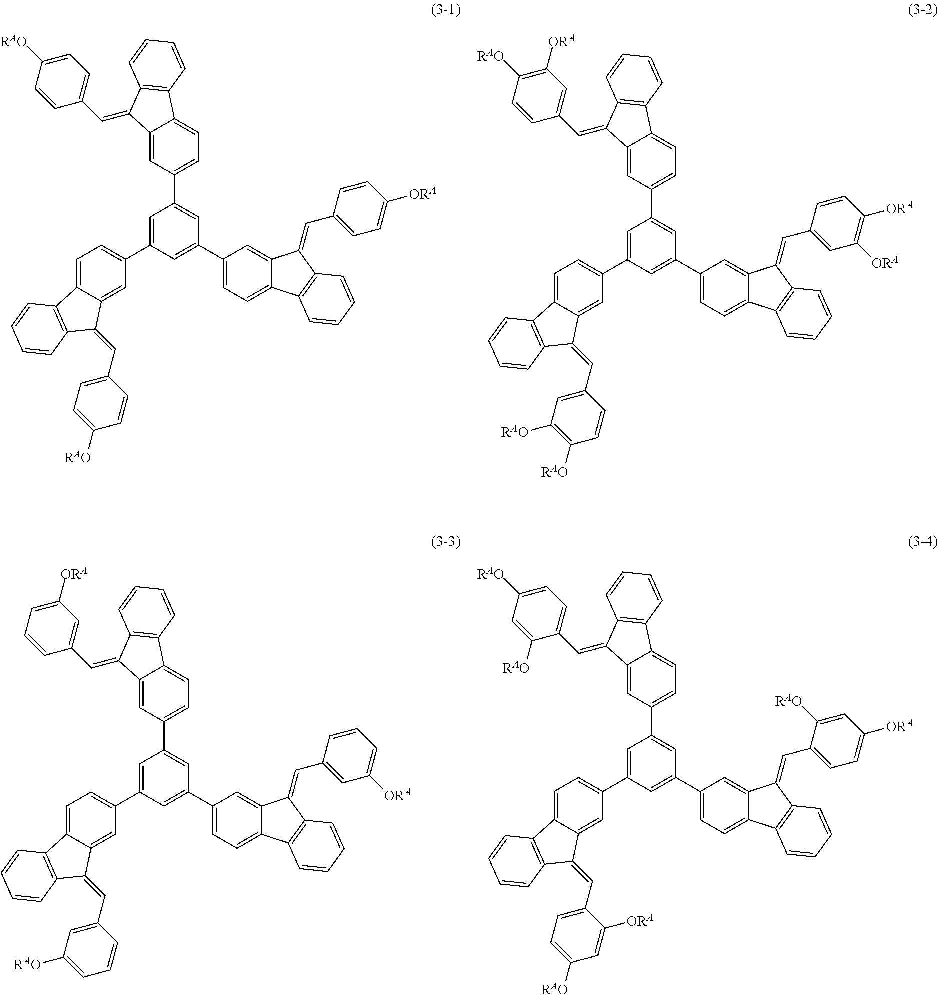

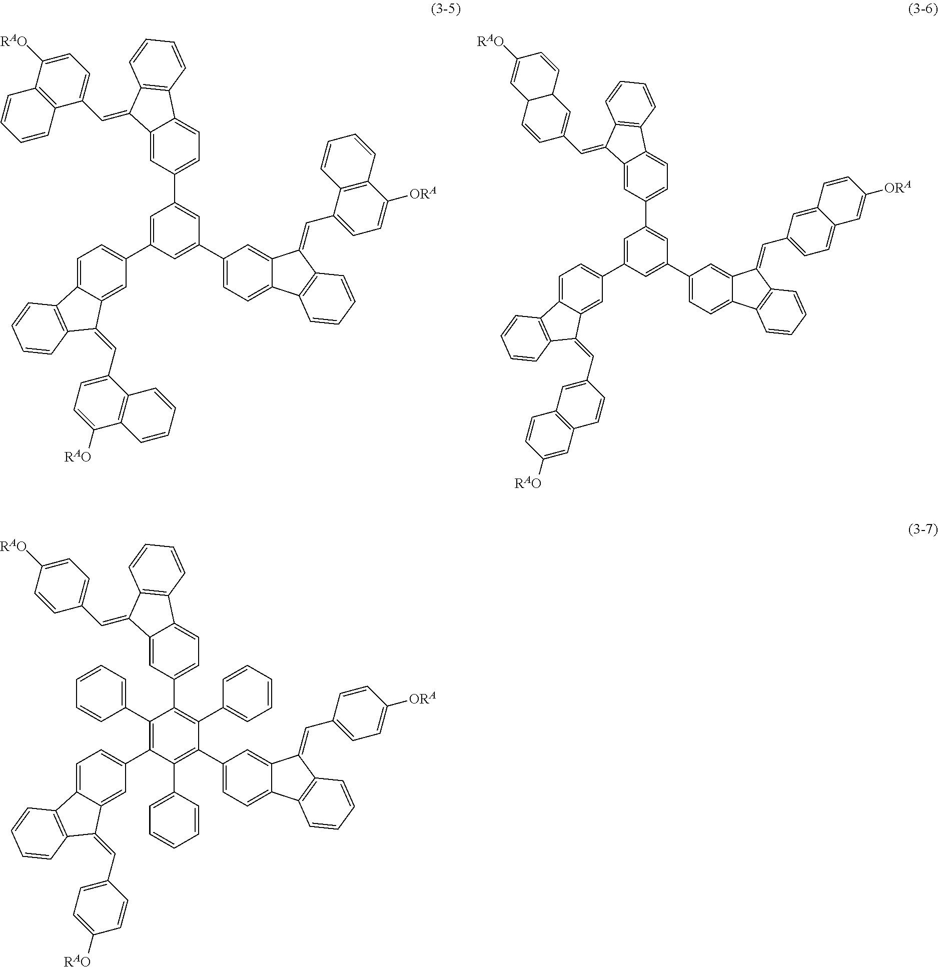

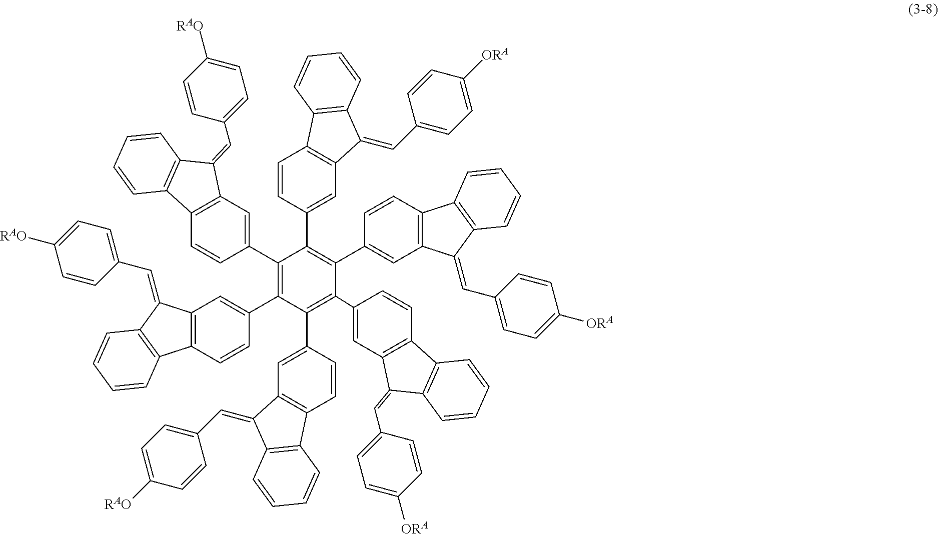

In the above formula, R^{A} is as described above.

As a method for synthesizing the aromatic ring-containing compound [A2], typically, a base skeleton part is synthesized first by preparing, for example, a ketone- or alkyne-substituted form of fluorene as a starting material and conducting the cyclization reaction of the ketone moiety or alkyne moiety in the presence of a catalyst and the like. Next, the 9-position of fluorene is modified with an aldehyde compound having a phenolic hydroxy group. Finally, the aromatic ring-containing compound [A2] can be produced by introducing —OR^{A} by the same method as the method for manufacturing the polymer [A1]. Other structures can also be synthesized by appropriately selecting the structures or the like of the starting material, the ketone form, and the aldehyde compound having a phenolic hydroxy group.

The content ratio of the compound (A) to the components other than the solvent in the composition for forming a resist underlayer film is 50% by mass or more. The lower limit of the content ratio is preferably 60% by mass, more preferably 70% by mass, still more preferably 80% by mass, particularly preferably 90% by mass. The upper limit of the content ratio is preferably 100% by mass (that is, the composition for forming a resist underlayer film contains only the compound [A] other than the solvent). In a case where the composition for forming a resist underlayer film contains an optional component, the upper limit of the content ratio is preferably 99% by mass, more preferably 98% by mass.

The lower limit of the content ratio of the compound [A] in the composition is preferably 0.01% by mass, more preferably 0.05% by mass, still more preferably 0.1% by mass, particularly preferably 0.5% by mass in the total mass of the compound [A] and the solvent [B]. The upper limit of the content ratio is preferably 30% by mass, more preferably 20% by mass, still more preferably 10% by mass, particularly preferably 5% by mass in the total mass of the compound [A] and the solvent [B].

### <Solvent [B]>

The solvent [B] is not particularly limited as long as it can dissolve or disperse the compound [A] and optional components contained as necessary.

Examples of the solvent [B] include a hydrocarbon-based solvent, an ester-based solvent, an alcohol-based solvent, a ketone-based solvent, an ether-based solvent, and a nitrogen-containing solvent. The solvent [B] may be used singly or two or more kinds thereof may be used in combination.

Examples of the hydrocarbon-based solvent include aliphatic hydrocarbon-based solvents such as n-pentane, n-hexane, and cyclohexane, and aromatic hydrocarbon-based solvents such as benzene, toluene, and xylene.

Examples of the ester-based solvent include carbonate-based solvents such as diethyl carbonate, acetic acid monoacetate ester-based solvents such as methyl acetate and ethyl acetate, lactone-based solvents such as γ-butyrolactone, polyhydric alcohol partial ether carboxylate-based solvents such as diethylene glycol monomethyl ether acetate and propylene glycol monomethyl ether acetate, and lactate ester-based solvents such as methyl lactate and ethyl lactate.

Examples of the alcohol-based solvent include monoalcohol-based solvents such as methanol, ethanol, and n-propanol, and polyhydric alcohol-based solvents such as ethylene glycol and 1,2-propylene glycol.

Examples of the ketone-based solvent include chain ketone-based solvents such as methyl ethyl ketone and methyl isobutyl ketone, and cyclic ketone-based solvents such as cyclohexanone.

Examples of the ether-based solvent include chain ether-based solvents such as n-butyl ether, cyclic ether-based solvents such as tetrahydrofuran, polyhydric alcohol ether-based solvents such as propylene glycol dimethyl ether, and polyhydric alcohol partial ether-based solvents such as diethylene glycol monomethyl ether.

Examples of the nitrogen-containing solvent include chain nitrogen-containing solvents such as N,N-dimethylacetamide, and cyclic nitrogen-containing solvents such as N-methylpyrrolidone.

As the solvent [B], an ester-based solvent or a ketone-based solvent is preferable, a polyhydric alcohol partial ether carboxylate-based solvent or a cyclic ketone-based solvent is more preferable, and propylene glycol monomethyl ether acetate or cyclohexanone is still more preferable.

The lower limit of the content ratio of the solvent [B] in the composition is preferably 50% by mass, more preferably 60% by mass, still more preferably 70% by mass, particularly preferably 80% by mass. The upper limit of the content ratio is preferably 99.99% by mass, more preferably 99.98% by mass, still more preferably 99.9% by mass, particularly preferably 99.5% by mass.

### [Optional Component]

The composition for forming a resist underlayer film may contain an optional component as long as the effects of the present disclosure are not impaired. Examples of the optional component include an acid generator, a crosslinking agent, a surfactant, a sensitizer, a defoaming agent, and other polymers different from the polymer [A1]. The optional component may be used singly, or two or more kinds thereof may be used in combination. As the defoaming agent, publicly known defoaming agents and the like can be used, and examples thereof include an alcohol defoaming agent, a phosphate ester defoaming agent, a fatty acid ester defoaming agent, a polyether defoaming agent, and a silicone defoaming agent. Examples of the fatty acid ester defoaming agent include methyl laurate, methyl palmitate, methyl stearate, propyl butyrate, butyl butyrate, ethyl isovalerate, and isobutyl propionate, and propyl butyrate and butyl butyrate are preferable. As the defoaming agent, a ketone-based solvent such as 2-heptanone may be used. Examples of the other polymers include a polymer having a repeating unit containing a sulfonate ester structure, and a polymer having a repeating unit containing a structure in which two perfluoroalkyl groups and one hydroxy group are bonded to one carbon atom.

### [Method for Preparing Composition]

The composition for forming a resist underlayer film can be prepared by mixing the compound [A], the solvent [B] and, as necessary, an optional component in a prescribed ratio and preferably filtering the resulting mixture through a membrane filter having a pore size of 0.5 μm or less and the like.

### [Silicon-Containing Film Forming Step]

In this step performed before the application step (I), a silicon-containing film is formed directly or indirectly on a substrate. If the substrate has a pattern, it is preferable to omit this step.

Examples of the substrate include metallic or semimetallic substrates such as a silicon substrate, an aluminum substrate, a nickel substrate, a chromium substrate, a molybdenum substrate, a tungsten substrate, a copper substrate, a tantalum substrate, and a titanium substrate. Among them, a silicon substrate is preferred. The substrate may be a substrate having a silicon nitride film, an alumina film, a silicon dioxide film, a tantalum nitride film, or a titanium nitride film formed thereon.

The silicon-containing film can be formed by, for example, coating with a composition for forming a silicon-containing film, chemical vapor deposition (CVD), or atomic layer deposition (ALD). Examples of a method for forming a silicon-containing film through the application of a composition for forming a silicon-containing film include a method including curing, by lithographic exposure and/or heating, a coating film formed by applying the composition for forming a silicon-containing film directly or indirectly to the resist underlayer film. As a commercially available product of the composition for forming a silicon-containing film, for example, “NFC SOG01”, “NFC SOGO4”, “NFC SOG080”, which are all manufactured by JSR Corporation, can be used. By chemical vapor deposition (CVD) or atomic layer deposition (ALD), a silicon oxide film, a silicon nitride film, a silicon oxynitride film, or an amorphous silicon film can be formed.

Examples of a case where the silicon-containing film is formed indirectly on a substrate include a case where the silicon-containing film is formed on a low dielectric insulating film formed on the substrate, a metal hard mask (TiO₂ or the like), or a carbon film by the CVD method.

### [Application Step (I)]

In this step, a composition for forming a resist underlayer film is applied directly or indirectly to a substrate. The method of the application of the composition for forming a resist underlayer film is not particularly limited, and the application can be performed by an appropriate method such as spin coating, cast coating, or roll coating. As a result, a coating film is formed, and volatilization of the solvent [B] or the like occurs, so that a resist underlayer film is formed.

The case where the composition for forming a resist underlayer film is applied indirectly to the substrate may be a case where the composition for forming a resist underlayer film is applied to an organic underlayer film formed on a substrate having no pattern.

The substrate may have a pattern. In this case, it is preferable to apply a composition for forming a resist underlayer film directly to a substrate. Since the composition for forming a resist underlayer film is excellent in embeddability and flatness, even when the substrate has a pattern, a good resist underlayer film can be formed while the gap between patterns is filled. Examples of the shape of the pattern include a trench pattern, a line-and-space pattern, a hole pattern, and a pillar pattern. Examples of the trench pattern and the line-and-space pattern include a pattern including a recess having a width of 5 nm or more and 100 nm or less and a depth of 5 nm or more and 500 nm or less. Examples of the hole pattern include a pattern including holes having a diameter of 5 nm or more and 100 nm or less and a depth of 5 nm or more and 500 nm or less. Examples of the pillar pattern include a pattern including pillars each having a side of 5 nm or more and 100 nm or less and a height of 5 nm or more and 500 nm or less in the case of a quadrangular prism, and a pattern including pillars each having a diameter of 5 nm or more and 100 nm or less and a height of 5 nm or more and 500 nm or less in the case of a cylinder.

Next, the coating film formed by the application is heated. The formation of the resist underlayer film is promoted by heating the coating film. More specifically, volatilization or the like of the solvent [B] is promoted by heating the coating film.

The heating of the coating film may be performed either in the air atmosphere or in a nitrogen atmosphere. The lower limit of the heating temperature is preferably 200° C., more preferably 250° C., and still more preferably 300° C. The upper limit of the heating temperature is preferably 550° C., and more preferably 500° C., and still more preferably 450° C. The lower limit of the heating time is preferably 15 seconds, and more preferably 30 seconds. The upper limit of the time is preferably 1,200 seconds, and more preferably 600 seconds.

After the applying step (I), the resist underlayer film may be subjected to exposure. After the applying step, the resist underlayer film may be exposed to plasma. After the applying step, the resist underlayer film may be ion-implanted. When the resist underlayer film is exposed, the etching resistance of the resist underlayer film is improved. When the resist underlayer film is exposed to plasma, the etching resistance of the resist underlayer film is improved. When the resist underlayer film is subjected to ion implantation, the etching resistance of the resist underlayer film is improved.

The radiation to be used for exposure of the resist underlayer film is appropriately selected from among electromagnetic waves such as visible rays, ultraviolet rays, far ultraviolet rays, X-rays, and γ-rays and corpuscular rays such as electron beam, molecular beams, and ion beams.

Examples of the method for exposing the resist underlayer film to plasma include a direct method in which a substrate is placed in each gas atmosphere and plasma discharge is performed. As plasma exposure conditions, usually, the gas flow rate is 50 cc/min or more and 100 cc/min or less, and the supply power is 100 W or more and 1,500 W or less.

The lower limit of the time of the exposure to plasma is preferably 10 seconds, more preferably 30 seconds, and still more preferably 1 minute. The upper limit of the time is preferably 10 minutes, more preferably 5 minutes, and still more preferably 2 minutes.

The plasma is generated, for example, under an atmosphere of a mixed gas of H₂ gas and Ar gas. In addition to the H₂ gas and the Ar gas, a carbon-containing gas such as a CF₄ gas or a CH₄ gas may be introduced. At least one among a CF₄ gas, an NF₃ gas, a CHF₃ gas, a CO₂ gas, a CH₂F₂ gas, a CH₄ gas, and a C₄F₈ gas may be introduced instead of one or both of the H₂ gas and the Ar gas.

In the ion implantation into the resist underlayer film, a dopant is implanted into the resist underlayer film. The dopant may be selected from the group consisting of boron, carbon, nitrogen, phosphorus, arsenic, aluminum, and tungsten. The implantation energy utilized to apply a voltage to the dopant may be from about 0.5 keV to 60 keV depending on the type of the dopant to be utilized and a desired depth of implantation.

The lower limit of the average thickness of the resist underlayer film to be formed is preferably 1 nm, more preferably 3 nm, and still more preferably 5 nm. The upper limit of the average thickness is preferably 500 nm, more preferably 200 nm, and still more preferably 100 nm. The average thickness is measured as described in Examples.

### [Application Step (II)]

In this step, a composition for forming a resist film is directly or indirectly applied on the resist underlayer film formed by the step of applying a composition for forming a resist underlayer film. The method of applying the composition for forming a resist film is not particularly limited, and examples thereof include a spin coating method.

The case where the composition for forming a resist film is applied indirectly to the resist underlayer film may be, for example, a case where the composition for forming a resist film is applied to a surface-modifying film formed on the resist underlayer film.

Describing this step in more detail, for example, a composition for forming a resist film is applied such that a resist film formed has a prescribed thickness, and then prebaking (hereinafter also referred to as “PB”) is performed to volatilize the solvent in the coating film. As a result, a resist film is formed.

The PB temperature and the PB time may be appropriately determined according to the type and the like of the composition for forming a resist film to be used. The lower limit of the PB temperature is preferably 30° C., more preferably 50° C. The upper limit of the PB temperature is preferably 200° C., more preferably 150° C. The lower limit of the PB time is preferably 10 seconds, more preferably 30 seconds. The upper limit of the PB time is preferably 600 seconds, more preferably 300 seconds.

The composition for forming a resist film used in this step is suitably a composition that is exposed to extreme ultraviolet rays, and examples of the composition include a positive or negative chemically amplified resist composition that contains a radiation-sensitive acid generator and a metal-containing resist composition that contains a metal such as tin, zirconium, or hafnium.

### [Exposure Step]

In this step, a resist film formed in the step of applying a composition for forming a resist film is exposed to extreme ultraviolet (EUV) rays. The exposure conditions can be appropriately determined depending on the type of the composition for forming a resist film to be used, and the like.

In this step, post exposure baking (hereinafter, also referred to as “PEB”) can be performed after the exposure in order to improve the resist film performance such as resolution, pattern profile, and developability. The PEB temperature and the PEB time may be appropriately determined according to the type and the like of the composition for forming a resist film to be used. The lower limit of the PEB temperature is preferably 50° C., more preferably 70° C. The upper limit of the PEB temperature is preferably 200° C., more preferably 150° C. The lower limit of the PEB time is preferably 10 seconds, more preferably 30 seconds. The upper limit of the duration of PEB is preferably 600 seconds, more preferably 300 seconds.

### [Development Step]

In this step, the exposed resist film is developed. At this time, a part of the resist underlayer film may also be developed. Examples of the developer to be used for the development include an aqueous alkaline solution (alkaline developer) and an organic solvent-containing solution (organic solvent developer).

The basic solution for the alkali development is not particularly limited, and a publicly known basic solution can be used. Examples of the basic solution for the alkali development include, in the alkaline development, an alkaline aqueous solution obtained by dissolving at least one alkaline compound such as sodium hydroxide, potassium hydroxide, sodium carbonate, sodium silicate, sodium metasilicate, ammonia water, ethylamine, n-propylamine, diethylamine, di-n-propylamine, triethylamine, methyldiethylamine, ethyldimethylamine, triethanolamine, tetramethyl ammonium hydroxide (TMAH), pyrrole, piperidine, choline, 1,8-diazabicyclo-[5.4.0]-7-undecene, and 1,5-diazabicyclo-[4.3.0]-5-nonene. Among them, an aqueous TMAH solution is preferable, and a 2.38% by mass aqueous TMAH solution is more preferable.

Examples of the organic solvent developer in the case of performing organic solvent development include the same developers as those disclosed as the examples of the solvent [B] described above. As the organic solvent developer, an ester-based solvent, an ether-based solvent, an alcohol-based solvent, a ketone-based solvent and/or a hydrocarbon-based solvent is preferable, a ketone-based solvent is more preferable, and 2-heptanone is particularly preferable.

In this step, washing and/or drying may be performed after the development.

### [Etching Step]

Subsequently, etching using the resist pattern (and the resist underlayer film pattern) formed in the developing step as a mask may be performed. The number of times of the etching may be once. Alternatively, etching may be performed a plurality of times, that is, etching may be sequentially performed using a pattern obtained by etching as a mask. From the viewpoint of obtaining a pattern having a favorable shape, it is preferable to perform etching a plurality of times. Dry etching is preferable from the viewpoint of achieving a favorable shape of the pattern of the substrate. In the dry etching, for example, gas plasma such as oxygen plasma is used. As a result of the etching, a semiconductor substrate having a prescribed pattern is obtained.

The dry etching can be performed using, for example, a publicly known dry etching apparatus. The etching gas used for dry etching can be appropriately selected according to the elemental composition of the film to be etched, and for example, fluorine-based gases such as CHF₃, CF₄, C₂F₆, C₃F₈, and SF₆, chlorine-based gases such as Cl₂ and BCl₃, oxygen-based gases such as O₂, O₃, and H₂O, reducing gases such as H₂, CO, CO₂, CH₄, C₂H₂, C₂H₄, C₂H₆, C₃H₄, C₃H₆, C₃H₈, HF, HI, HBr, HCl, NO, NH₃ and BCl₃, and inert gases such as He, N₂ and Ar are used. These gases can also be mixed and used. When the substrate is etched using the pattern of the resist underlayer film as a mask, a fluorine-based gas is usually used.

### EXAMPLES

Hereinbelow, the present invention will specifically be described on the basis of examples, but is not limited to these examples.

### [Weight Average Molecular Weight (Mw) and Number Average Molecular Weight (Mn)]

The Mw and Mn of a polymer were measured by gel permeation chromatography (detector: differential refractometer) with monodisperse polystyrene standards using GPC columns (“G2000HXL”×2 and “G3000HXL”×1) manufactured by Tosoh Corporation under the following analysis conditions: flow rate: 1.0 mL/min; elution solvent: tetrahydrofuran; column temperature: 40° C.

### [Modification Rate of Phenolic Hydroxy Group]

The modification rate of the phenolic hydroxy group of the compound [A] was calculated on the basis of the number of hydroxy groups in the raw material used for synthesis and the number of the modifier used for modifying the phenolic hydroxy group.

### [Average Thickness of Film]

The average thickness of a film was determined as a value attained by measuring the film thickness at arbitrary nine points at intervals of 5 cm including the center of the resist underlayer film formed on a silicon wafer (substrate) using a spectroscopic ellipsometer (“M2000D” available from J. A. WOOLLAM Co.) and calculating the average value of the film thicknesses.

### <Synthesis of Compound [A]>

Compounds (p-1) to (p-5) as synthesis raw materials of the compound [A] were synthesized by the following procedure.

### [Synthesis Example 1-1](Synthesis of Compound (p-1))

A reaction vessel was charged with 10.0 g of 2,7-dihydroxynaphthalene, 6.6 g of benzaldehyde, and 49.8 g of 1-butanol in a nitrogen atmosphere, and stirring was performed to dissolve the compounds. A 1-butanol solution (8.8 g) of 2.4 g of p-toluenesulfonic acid monohydrate was added into the reaction vessel, and the mixture was heated to 110° C., and the reaction was conducted for 12 hours. After completion of the reaction, the reaction solution was transferred to a separatory funnel, 100 g of methyl isobutyl ketone and 200 g of water were added thereto, and the organic phase was washed. After the aqueous phase was separated, the obtained organic phase was washed several times with water. Thereafter, the organic phase was concentrated using an evaporator, and the residue was dropped into 100 g of methanol to obtain a precipitate. The precipitate was collected by suction filtration and washed several times with 50 g of methanol. Thereafter, the product was dried in a vacuum dryer at 60° C. for 12 hours to obtain compound (p-1) having a repeating unit represented by formula (p-1). The Mw of the compound (p-1) was 2560.

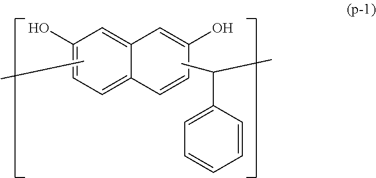

### [Synthesis Example 1-2](Synthesis of Compound (p-2))

Compound (p-2) having a repeating unit represented by formula (p-2) was obtained by performing a reaction under the same conditions as in [Synthesis Example 1-1], except that 13.7 g of 1-hydroxypyrene was used in place of 10.0 g of 2,7-dihydroxynaphthalene, and 8.7 g of 3,4-dihydroxybenzaldehyde was used in place of 6.6 g of benzaldehyde. The Mw of the compound (p-2) was 3800.

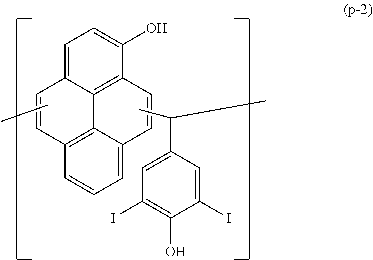

### [Synthesis Example 1-3](Synthesis of Compound (p-3))

Compound (p-3) having a repeating unit represented by formula (p-3) was obtained by performing a reaction under the same conditions as in [Synthesis Example 1-1], except that 18.1 g of 1,1-bis(4-hydroxyphenyl)-1-phenylethane was used in place of 10.0 g of 2,7-dihydroxynaphthalene, and 8.7 g of 2,4-dihydroxybenzaldehyde was used in place of 6.6 g of benzaldehyde. The Mw of the compound (p-3) was 4150.

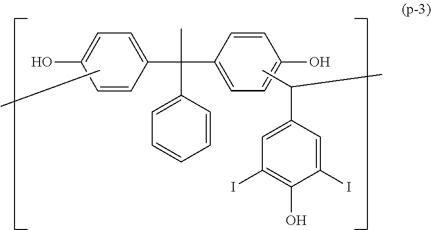

### [Synthesis Example 1-4](Synthesis of Compound (p-4))

A reaction vessel was charged with 10.0 g of 1,3,5-benzenetriyltris-9H-fluorene, 7.1 g of 4-hydroxybenzaldehyde, and 60.0 g of dimethylacetamide in a nitrogen atmosphere, and the mixture was suspended. Diazabicycloundecene (8.8 g) was added, and the resulting mixture was reacted at 120° C. for 12 hours. After completion of the reaction, 300.0 g of methyl isobutyl ketone and 200.0 g of a 5% aqueous oxalic acid solution were added, and the organic phase was separated. The organic phase was washed with water several times, and then the obtained organic phase was concentrated using an evaporator and added dropwise to 200 g of methanol, affording a precipitate. The precipitate was collected by suction filtration and washed several times with 50.0 g of methanol. Thereafter, the washed product was dried in a vacuum dryer at 60° C. for 12 hours, affording compound (p-4) represented by formula (p-4).

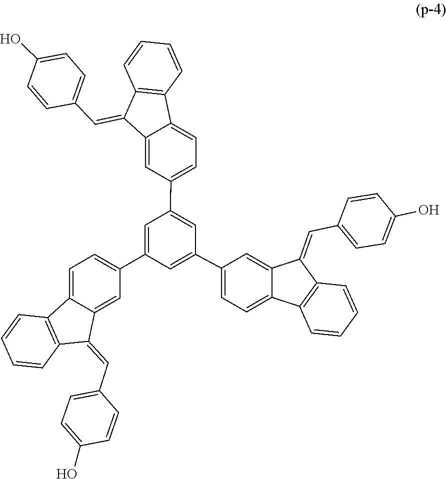 [SMILES: Oc1ccc(/C=C2\c3ccccc3-c3ccc(-c4cc(-c5ccc6c(c5)/C(=C/c5ccc(O)cc5)c5ccccc5-6)cc(-c5ccc6c(c5)/C(=C/c5ccc(O)cc5)c5ccccc5-6)c4)cc32)cc1]

### [Synthesis Example 1-5](Synthesis of Compound (p-5))

Compound (p-5) represented by formula (p-5) was obtained by conducting a reaction under the same conditions as in [Synthesis Example 1-4] except that 8.0 g of 3,4-dihydroxybenzaldehyde was used in place of 7.1 g of 4-hydroxybenzaldehyde.

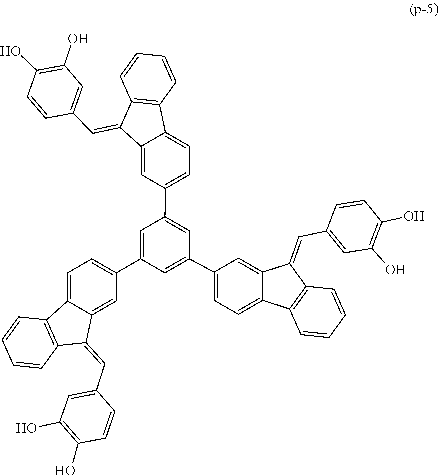 [SMILES: Oc1ccc(/C=C2\c3ccccc3-c3ccc(-c4cc(-c5ccc6c(c5)/C(=C/c5ccc(O)c(O)c5)c5ccccc5-6)cc(-c5ccc6c(c5)/C(=C/c5ccc(O)c(O)c5)c5ccccc5-6)c4)cc32)cc1O]

As modifiers for the phenolic hydroxy groups of the compound [A], the following compounds (a-1) to (a-8), the following compounds (b-1) to (b-3), the following compounds (c-1) to (c-4), and the following compounds (d-1) to (d-2) were used. The following compounds (a-1) to (a-8), the following compounds (b-1) to (b-3), and the following compounds (c-1) to (c-4) each provide a heteroatom-containing group, and the following compounds (d-1) to (d-2) each provide an organic group other than the heteroatom-containing groups (that is, an organic group (A)).

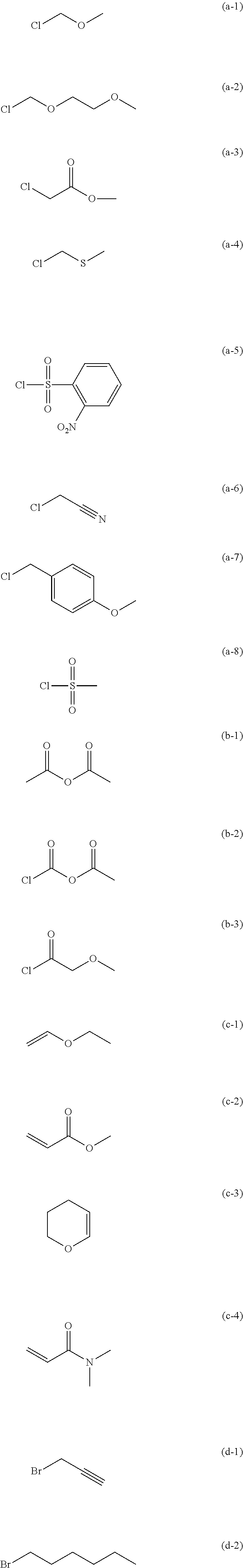

Compounds [A] were each synthesized by the following procedure.

### [Synthesis Example 2-1](Synthesis of Compound (A-1))

In a reaction vessel, 10.0 g of the compound (p-1) was dissolved in 50.0 g of tetrahydrofuran under a nitrogen atmosphere, the mixture was cooled to 10° C. or lower, 3.12 g of N,N-diisopropylethylamine was added, 1.95 g of chloromethyl methyl ether (a-1) was added dropwise, and the mixture was returned to room temperature and reacted for 1 hour. After completion of the reaction, the reaction solution was transferred to a separatory funnel, 150 g of methyl isobutyl ketone and 200 g of water were added thereto, and the organic phase was washed. After the aqueous phase was separated, the obtained organic phase was washed several times with water. Thereafter, the organic phase was concentrated using an evaporator, and the residue was dropped into 150 g of methanol, affording a precipitate. The precipitate was collected by suction filtration and washed several times with 50 g of methanol. Then, the washed product was dried at 60° C. for 12 hours in a vacuum dryer, affording compound (A-1). In the formula, the numerical values are the proportion x of the hydrogen atoms constituting R^{A} and the proportion y of the heteroatom-containing groups as modifying groups (and the proportion z of the organic groups (A) (if any)). * is a bond to an oxygen atom. The same applies to formula.

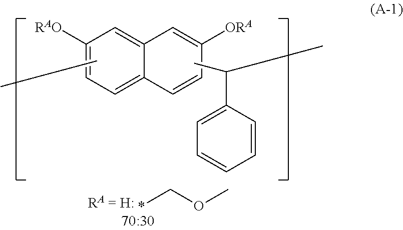

### [Synthesis Examples 2-2 to 2-6 and 2-11 to 2-13](Synthesis of Compounds (A-2) to (A-6) and (A-11) to (A-13))

Compounds (A-2) to (A-6) and (A-11) to (A-13) were obtained as products under the same reaction conditions as in Synthesis Example A-1 except that the modifiers shown in Table 1 were used.

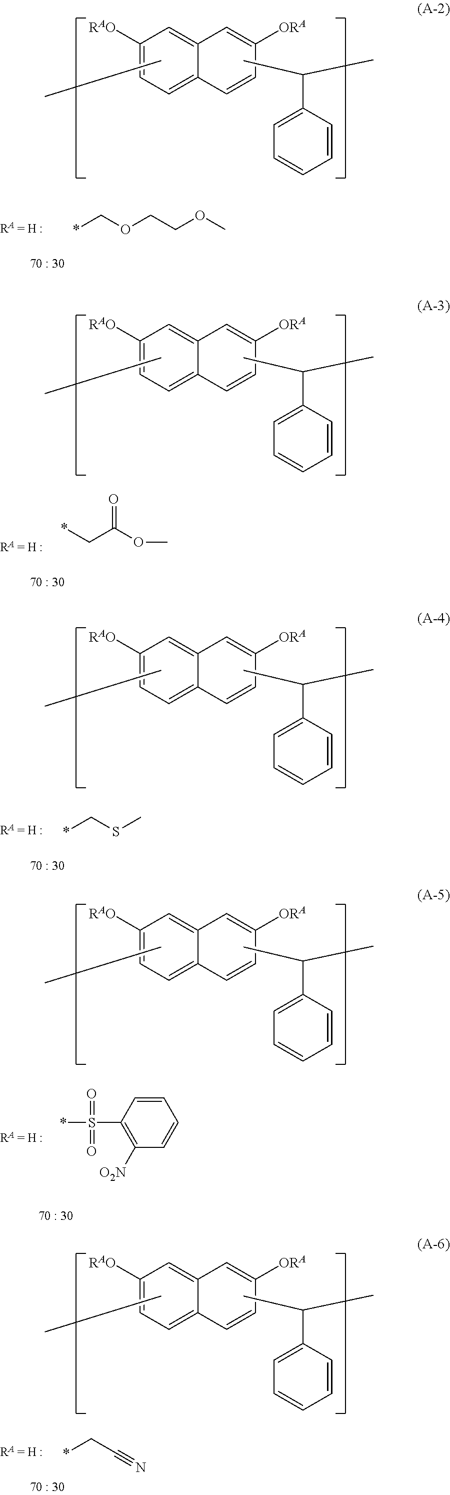

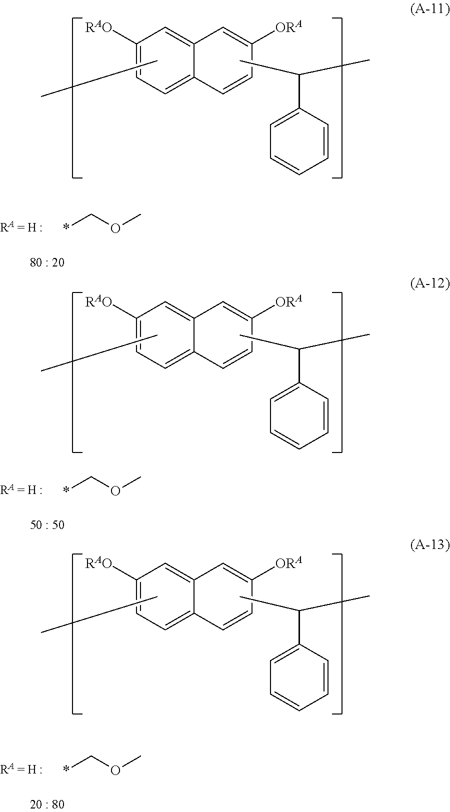

### [Synthesis Example 2-7](Synthesis of Compound (A-7))

In a reaction vessel, 10.0 g of the compound (p-1) was dissolved in 50.0 g of tetrahydrofuran under a nitrogen atmosphere, 0.49 g of N,N-dimethylaminopyridine was added, 2.47 g of acetic anhydride (b-1) was added dropwise, and the mixture was reacted at 50° C. for 1 hour. After completion of the reaction, the reaction solution was transferred to a separatory funnel, 150 g of methyl isobutyl ketone and 200 g of water were added thereto, and the organic phase was washed. After the aqueous phase was separated, the obtained organic phase was washed several times with water. Thereafter, the organic phase was concentrated using an evaporator, and the residue was dropped into 150 g of methanol, affording a precipitate. The precipitate was collected by suction filtration and washed several times with 50 g of methanol. Thereafter, the washed product was dried in a vacuum dryer at 60° C. for 12 hours to obtain compound (A-7) having a repeating unit represented by formula (A-7).

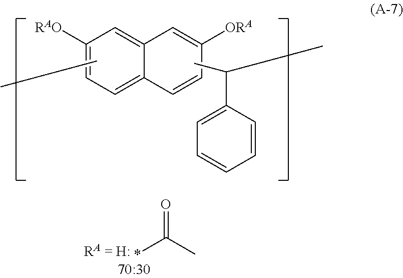

### [Synthesis Example 2-8](Synthesis of Compound (A-8))

Compound (A-8) was obtained as a product under the same reaction conditions as in Synthesis Example 2-7 except that the modifier shown in Table 1 was used.

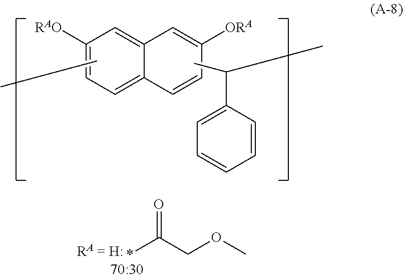

### [Synthesis Example 2-9](Synthesis of Compound (A-9))

In a reaction vessel, 10.0 g of the compound (p-1) was dissolved in 50.0 g of tetrahydrofuran under a nitrogen atmosphere, 1.74 g of ethyl vinyl ether (c-1) was added, 0.61 g of pyridinium p-toluenesulfonate was added dropwise, and the mixture was reacted at 50° C. for 3 hours. After completion of the reaction, the reaction solution was transferred to a separatory funnel, 150 g of methyl isobutyl ketone and 200 g of water were added thereto, and the organic phase was washed. After the aqueous phase was separated, the obtained organic phase was washed several times with water. Thereafter, the organic phase was concentrated using an evaporator, and the residue was dropped into 150 g of methanol, affording a precipitate. The precipitate was collected by suction filtration and washed several times with 50 g of methanol. Thereafter, the washed product was dried in a vacuum dryer at 60° C. for 12 hours to obtain compound (A-9) having a repeating unit represented by formula (A-9).

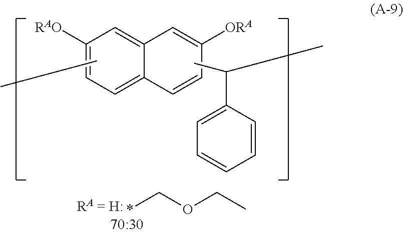

### [Synthesis Example 2-10](Synthesis of Compound (A-10))

Compound (A-10) was obtained as a product under the same reaction conditions as in Synthesis Example 2-9 except that the modifier shown in Table 1 was used.

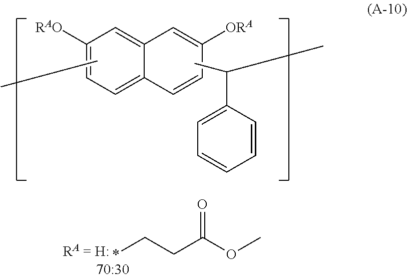

### [Synthesis Example 2-14](Synthesis of Compound (A-14))

In a reaction vessel, 10.0 g of the compound (p-1) was dissolved in 50.0 g of tetrahydrofuran under a nitrogen atmosphere, the mixture was cooled to 10° C. or lower, 8.33 g of N,N-diisopropylethylamine was added, 1.30 g of chloromethyl methyl ether (a-1) was added dropwise, and the mixture was returned to room temperature and reacted for 1 hour. Thereafter, 2.87 g of propargyl bromide (d-1) was added dropwise, and the resulting mixture was reacted at 60° C. for 2 hours. After completion of the reaction, the reaction solution was transferred to a separatory funnel, 150 g of methyl isobutyl ketone and 200 g of water were added thereto, and the organic phase was washed. After the aqueous phase was separated, the obtained organic phase was washed several times with water. Thereafter, the organic phase was concentrated using an evaporator, and the residue was dropped into 150 g of methanol, affording a precipitate. The precipitate was collected by suction filtration and washed several times with 50 g of methanol. Thereafter, the washed product was dried in a vacuum dryer at 60° C. for 12 hours to obtain compound (A-14) having a repeating unit represented by formula (A-14).

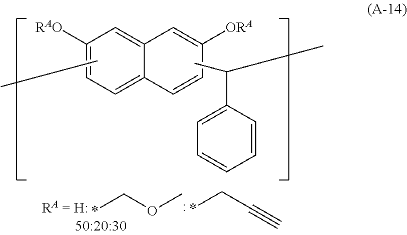

### [Synthesis Examples 2-15 and 2-28 to 2-29](Synthesis of Compounds (A-15) and (A-28) to (A-29))

Compounds (A-15) and (A-28) to (A-29) were obtained as products under the same reaction conditions as in Synthesis Example 2-14 except that the compounds and the modifiers shown in Table 1 were used.

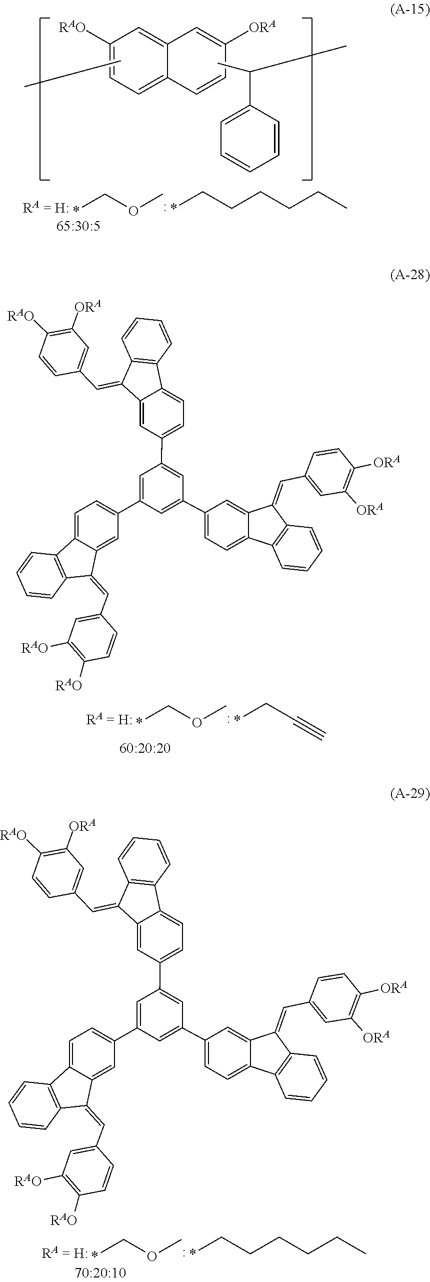

### [Synthesis Examples 2-16 to 2-21](Synthesis of Compounds (A-16) to (A-21))

Compounds (A-16) to (A-21) were obtained as products under the same reaction conditions as in Synthesis Example 2-1 except that the compounds and the modifiers shown in Table 1 were used.

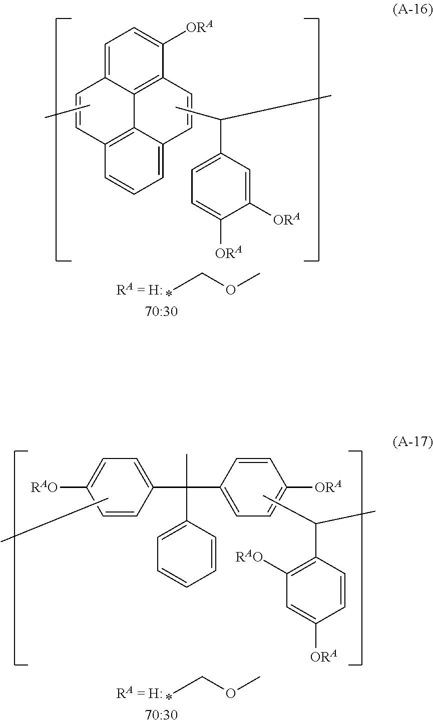

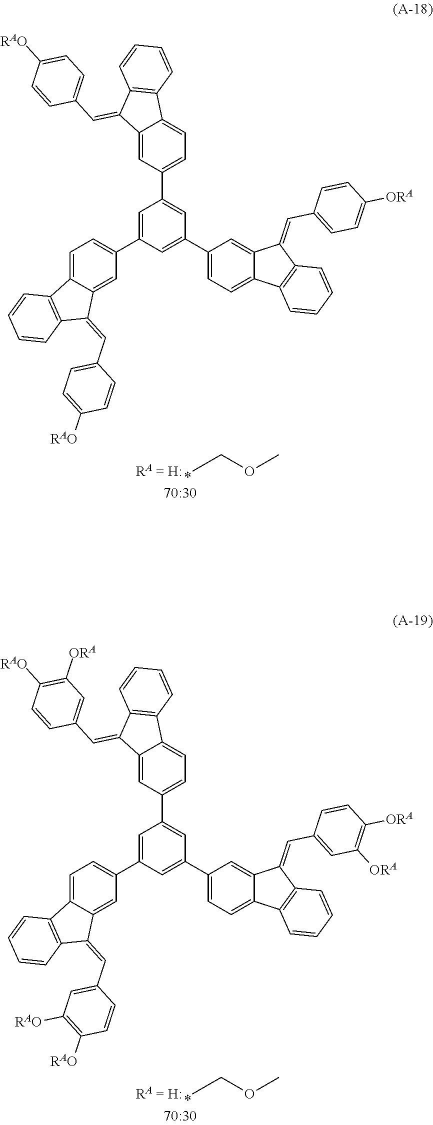

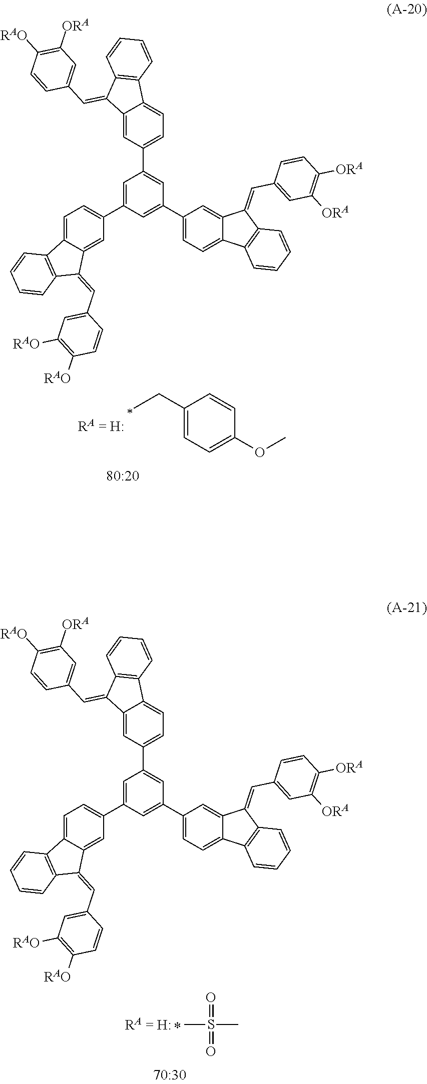

### [Synthesis Example 2-22](Synthesis of Compound (A-22))

Compound (A-22) was obtained as a product under the same reaction conditions as in Synthesis Example 2-7 except that the compound and the modifier shown in Table 1 were used.

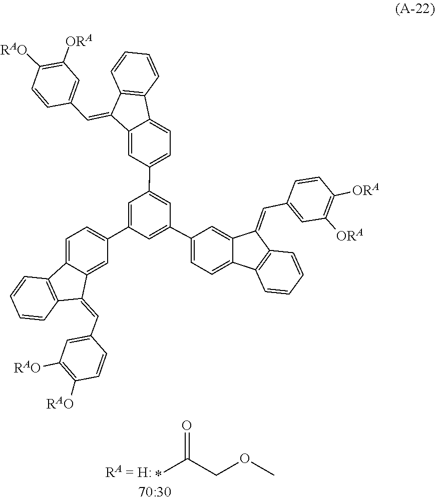

### [Synthesis Examples 2-23 to 2-24](Synthesis of Compounds (A-23) to (A-24))

Compounds (A-23) to (A-24) were obtained as products under the same reaction conditions as in Synthesis Example 2-9 except that the compounds and the modifiers shown in Table 1 were used.

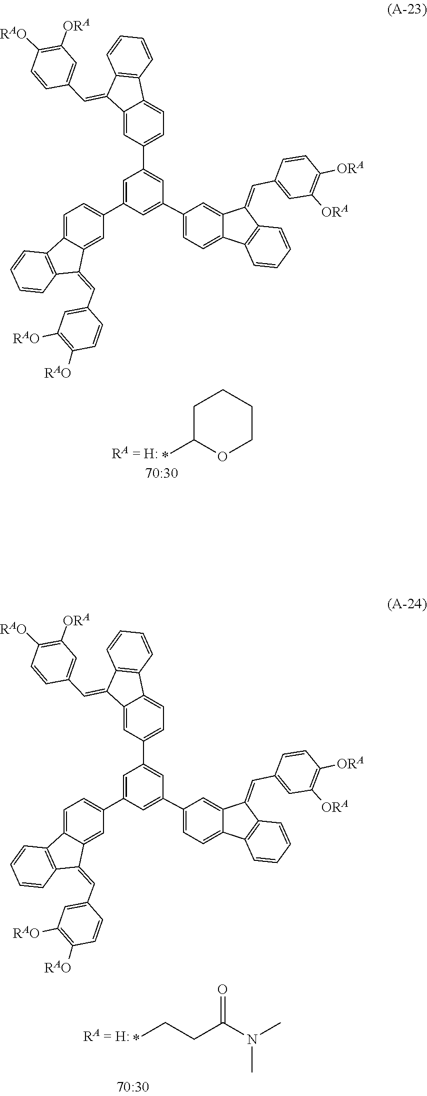

### [Synthesis Examples 2-25 to 2-27 and 2-30 to 2-31](Synthesis of Compounds (A-25) to (A-27) and (A-30) to (A-31))

Compounds (A-25) to (A-27) and (A-30) to (A-31) were obtained as products under the same reaction conditions as in Synthesis Example A-1 except that the compounds and the modifiers shown in Table 1 were used.

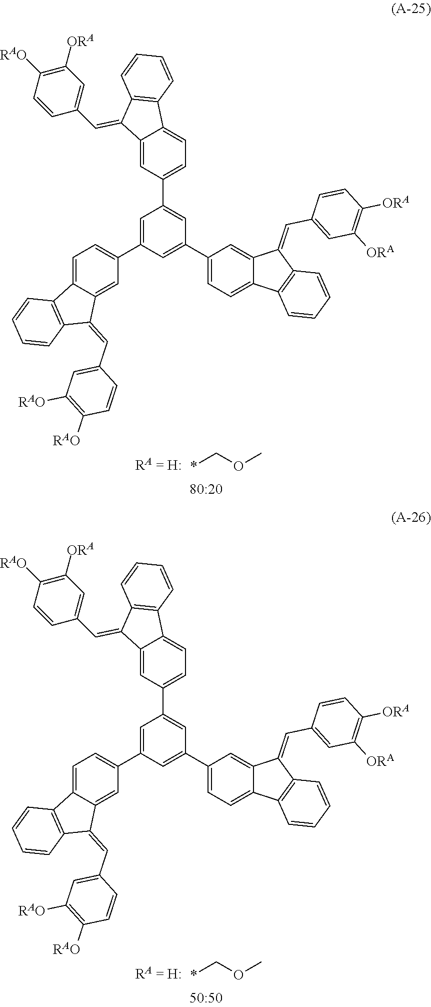

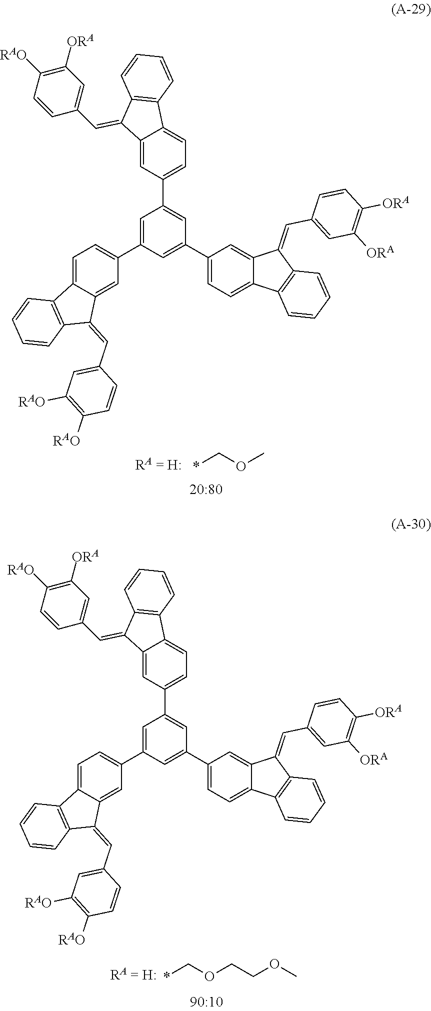

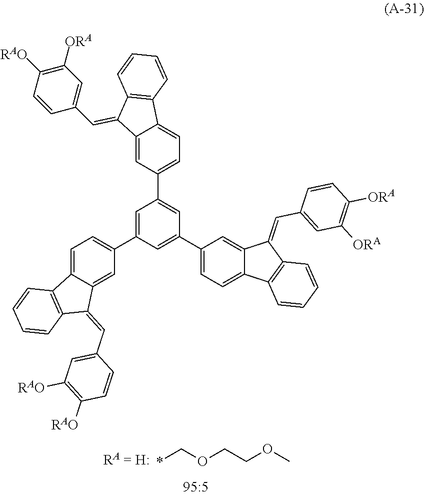

TABLE 1

| | | | | | | | | Proportion | Proportion y of | |
|---|---|---|---|---|---|---|---|---|---|---|
| | | Compound (p) | | Modifier | | | | x of | heteroatom- | Proportion z of |
| | Compound | | Mass | | Mass | | Mass | hydrogen | containing | organic group |
| | (A) | Type | (g) | Type | (g) | Type | (g) | atom | group | (A) |
| Synthesis | A-1 | p-1 | 10.0 | a-1 | 1.95 | — | — | 70 | 30 | — |
| Example 2-1 | | | | | | | | | | |
| Synthesis | A-2 | p-1 | 10.0 | a-2 | 3.01 | — | — | 70 | 30 | — |
| Example 2-2 | | | | | | | | | | |
| Synthesis | A-3 | p-1 | 10.0 | a-3 | 2.62 | — | — | 70 | 30 | — |
| Example 2-3 | | | | | | | | | | |
| Synthesis | A-4 | p-1 | 10.0 | a-4 | 2.33 | — | — | 70 | 30 | — |
| Example 2-4 | | | | | | | | | | |
| Synthesis | A-5 | p-1 | 10.0 | a-5 | 5.36 | — | — | 70 | 30 | — |
| Example 2-5 | | | | | | | | | | |
| Synthesis | A-6 | p-1 | 10.0 | a-6 | 1.82 | — | — | 70 | 30 | — |
| Example 2-6 | | | | | | | | | | |
| Synthesis | A-7 | p-1 | 10.0 | b-1 | 2.47 | — | — | 70 | 30 | — |
| Example 2-7 | | | | | | | | | | |
| Synthesis | A-8 | p-1 | 10.0 | b-2 | 2.62 | — | — | 70 | 30 | — |
| Example 2-8 | | | | | | | | | | |
| Synthesis | A-9 | p-1 | 10.0 | c-1 | 1.74 | — | — | 70 | 30 | — |
| Example 2-9 | | | | | | | | | | |
| Synthesis | A-10 | p-1 | 10.0 | c-2 | 2.08 | — | — | 70 | 30 | — |
| Example 2-10 | | | | | | | | | | |
| Synthesis | A-11 | p-1 | 10.0 | a-1 | 1.30 | — | — | 80 | 20 | — |
| Example 2-11 | | | | | | | | | | |
| Synthesis | A-12 | p-1 | 10.0 | a-1 | 3.24 | — | — | 50 | 50 | — |
| Example 2-12 | | | | | | | | | | |
| Synthesis | A-13 | p-1 | 10.0 | a-1 | 5.19 | — | — | 20 | 80 | — |
| Example 2-13 | | | | | | | | | | |
| Synthesis | A-14 | p-1 | 10.0 | a-1 | 1.30 | d-1 | 2.87 | 50 | 20 | 30 |
| Example 2-14 | | | | | | | | | | |
| Synthesis | A-15 | p-1 | 10.0 | a-1 | 1.95 | d-2 | 0.67 | 65 | 30 | 5 |
| Example 2-15 | | | | | | | | | | |
| Synthesis | A-16 | p-2 | 10.0 | a-1 | 2.13 | — | — | 70 | 30 | — |
| Example 2-16 | | | | | | | | | | |
| Synthesis | A-17 | p-3 | 10.0 | a-1 | 2.35 | — | — | 70 | 30 | — |
| Example 2-17 | | | | | | | | | | |
| Synthesis | A-18 | p-4 | 10.0 | a-1 | 0.82 | — | — | 70 | 30 | — |
| Example 2-18 | | | | | | | | | | |
| Synthesis | A-19 | p-5 | 10.0 | a-1 | 1.56 | — | — | 70 | 30 | — |
| Example 2-19 | | | | | | | | | | |
| Synthesis | A-20 | p-5 | 10.0 | a-7 | 2.02 | — | — | 80 | 20 | — |
| Example 2-20 | | | | | | | | | | |
| Synthesis | A-21 | p-5 | 10.0 | a-8 | 2.21 | — | — | 70 | 30 | — |
| Example 2-21 | | | | | | | | | | |
| Synthesis | A-22 | p-5 | 10.0 | b-3 | 2.10 | — | — | 70 | 30 | — |
| Example 2-22 | | | | | | | | | | |
| Synthesis | A-23 | p-5 | 10.0 | c-3 | 1.63 | — | — | 70 | 30 | — |
| Example 2-23 | | | | | | | | | | |
| Synthesis | A-24 | p-5 | 10.0 | c-4 | 1.92 | — | — | 70 | 30 | — |
| Example 2-24 | | | | | | | | | | |
| Synthesis | A-25 | p-5 | 10.0 | a-1 | 1.04 | — | — | 80 | 20 | — |
| Example 2-25 | | | | | | | | | | |
| Synthesis | A-26 | p-5 | 10.0 | a-1 | 2.59 | — | — | 50 | 50 | — |
| Example 2-26 | | | | | | | | | | |
| Synthesis | A-27 | p-5 | 10.0 | a-1 | 4.15 | — | — | 20 | 80 | — |
| Example 2-27 | | | | | | | | | | |
| Synthesis | A-28 | p-5 | 10.0 | a-1 | 1.04 | d-1 | 1.53 | 60 | 20 | 20 |
| Example 2-28 | | | | | | | | | | |
| Synthesis | A-29 | p-5 | 10.0 | a-1 | 1.04 | d-2 | 1.06 | 70 | 20 | 10 |
| Example 2-29 | | | | | | | | | | |
| Synthesis | A-30 | p-5 | 10.0 | a-2 | 0.80 | — | — | 90 | 10 | — |
| Example 2-30 | | | | | | | | | | |
| Synthesis | A-31 | p-5 | 10.0 | a-2 | 0.40 | — | — | 95 | 5 | — |
| Example 2-31 | | | | | | | | | | |

### <Preparation of Composition>

The compounds [A], the comparative compounds, the solvents [B], the acid generators [C], the crosslinking agents [D], and other polymers [E] used for the preparation of compositions are shown below.

### [Compound [A]]

A-1 to A-31: Compounds (A-1) to (A-31) synthesized above

### [Comparative Compound]

p-1: Compounds (p-1) synthesized above
p-5: Compounds (p-5) synthesized above

### [Solvent [B]]

B-1: Propylene glycol monomethyl ether acetate

### [Acid Generator [C]]

C-1: Compound represented by formula (C-1)

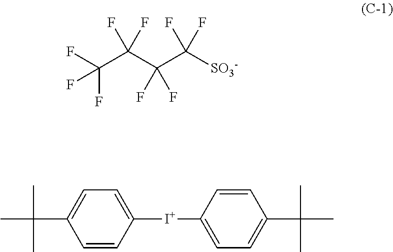

### [Crosslinking Agent [D]]

D-1: Compound represented by formula (D-1)

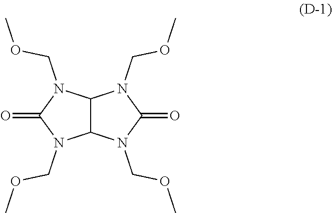

D-2: Compound represented by formula (D-2)

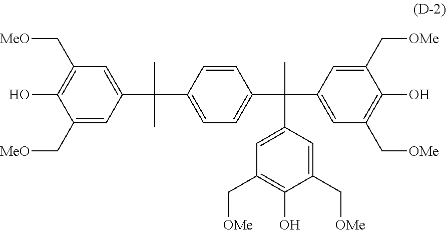 [SMILES: COCc1cc(C(C)(C)c2ccc(C(C)(c3cc(COC)c(O)c(COC)c3)c3cc(COC)c(O)c(COC)c3)cc2)cc(COC)c1O]

D-3: Compound represented by formula (D-3)

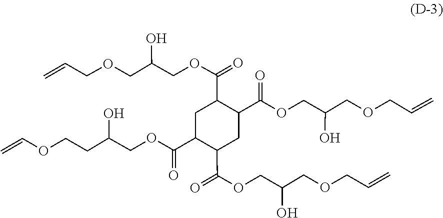 [SMILES: C=CCOCC(O)COC(=O)C1CC(C(=O)OCC(O)COCC=C)C(C(=O)OCC(O)COCC=C)CC1C(=O)OCC(O)CCOC=C]

D-4: Compound represented by formula (D-4)

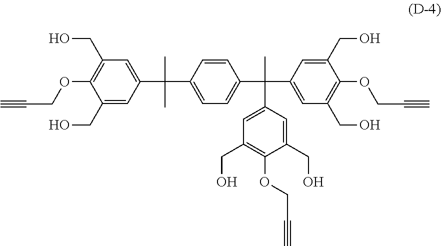 [SMILES: C#CCOc1c(CO)cc(C(C)(C)c2ccc(C(C)(c3cc(CO)c(OCC#C)c(CO)c3)c3cc(CO)c(OCC#C)c(CO)c3)cc2)cc1CO]

D-5: Compound represented by formula (D-5)

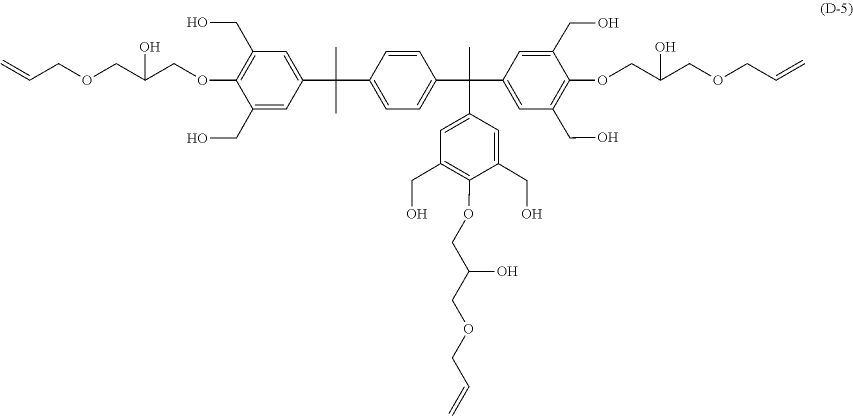 [SMILES: C=CCOCC(O)COc1c(CO)cc(C(C)(C)c2ccc(C(C)(c3cc(CO)c(OCC(O)COCC=C)c(CO)c3)c3cc(CO)c(OCC(O)COCC=C)c(CO)c3)cc2)cc1CO]

D-6: Compound represented by formula (D-6)

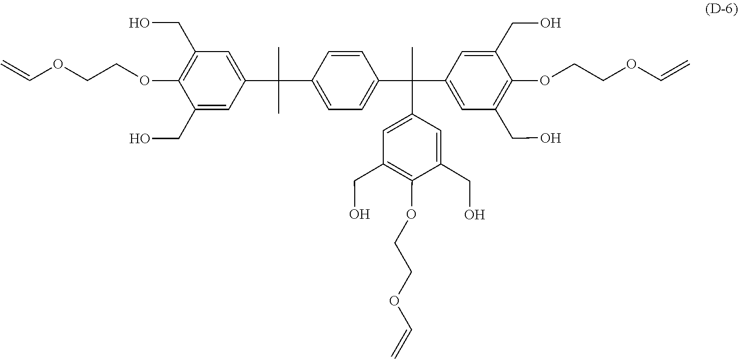 [SMILES: C=COCCOc1c(CO)cc(C(C)(C)c2ccc(C(C)(c3cc(CO)c(OCCOC=C)c(CO)c3)c3cc(CO)c(OCCOC=C)c(CO)c3)cc2)cc1CO]

D-7: Compound represented by formula (D-7)

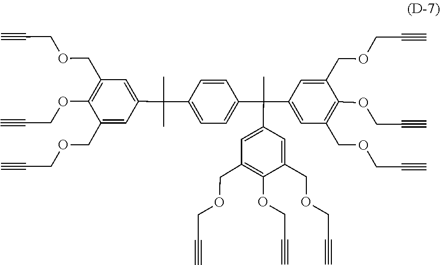 [SMILES: C#CCOCc1cc(C(C)(C)c2ccc(C(C)(c3cc(COCC#C)c(OCC#C)c(COCC#C)c3)c3cc(COCC#C)c(OCC#C)c(COCC#C)c3)cc2)cc(COCC#C)c1OCC#C]

D-8: Compound represented by formula (D-8)

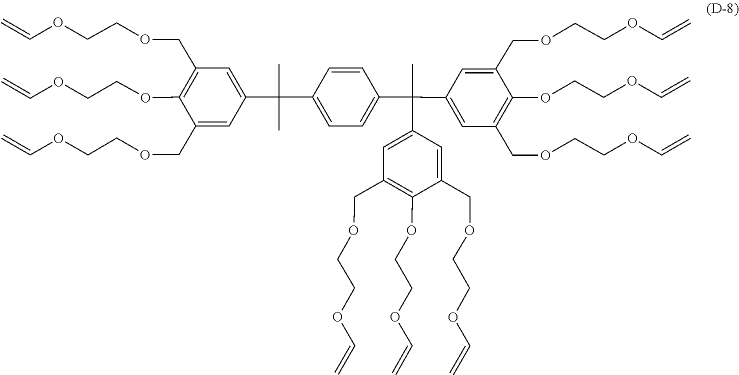 [SMILES: C=COCCOCc1cc(C(C)(C)c2ccc(C(C)(c3cc(COCCOC=C)c(OCCOC=C)c(COCCOC=C)c3)c3cc(COCCOC=C)c(OCCOC=C)c(COCCOC=C)c3)cc2)cc(COCCOC=C)c1OCCOC=C]

D-9: Compound represented by formula (D-9)

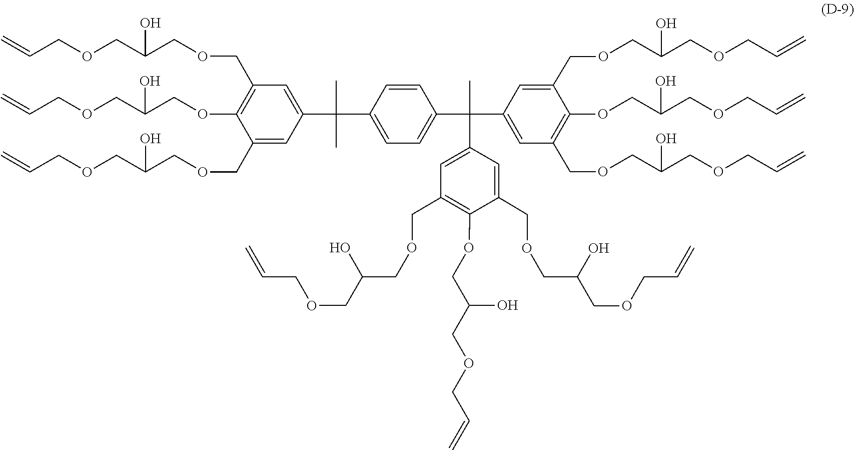 [SMILES: C=CCOCC(O)COCc1cc(C(C)(C)c2ccc(C(C)(c3cc(COCC(O)COCC=C)c(OCC(O)COCC=C)c(COCC(O)COCC=C)c3)c3cc(COCC(O)COCC=C)c(OCC(O)COCC=C)c(COCC(O)COCC=C)c3)cc2)cc(COCC(O)COCC=C)c1OCC(O)COCC=C]

D-10: Compound represented by formula (D-10)

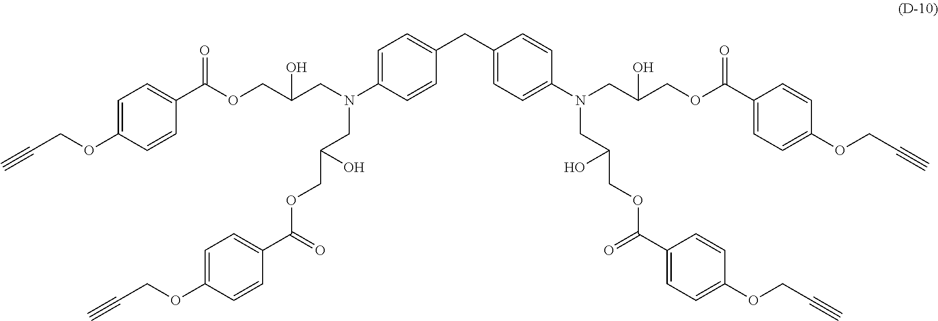 [SMILES: C#CCOc1ccc(C(=O)OCC(O)CN(CC(O)COC(=O)c2ccc(OCC#C)cc2)c2ccc(Cc3ccc(N(CC(O)COC(=O)c4ccc(OCC#C)cc4)CC(O)COC(=O)c4ccc(OCC#C)cc4)cc3)cc2)cc1]

D-11: Compound represented by formula (D-11)

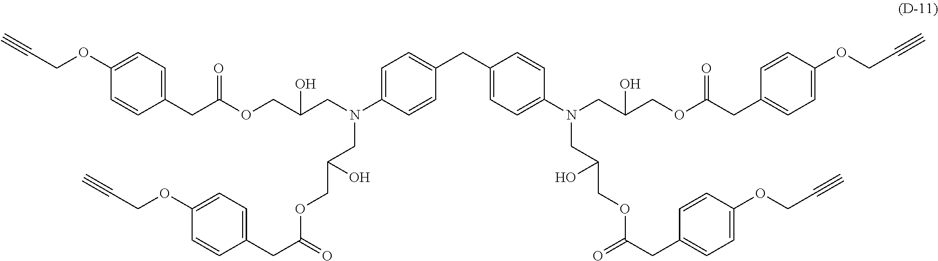 [SMILES: C#CCOc1ccc(CC(=O)OCC(O)CN(CC(O)COC(=O)Cc2ccc(OCC#C)cc2)c2ccc(Cc3ccc(N(CC(O)COC(=O)Cc4ccc(OCC#C)cc4)CC(O)COC(=O)Cc4ccc(OCC#C)cc4)cc3)cc2)cc1]

D-12: Compound represented by formula (D-12)

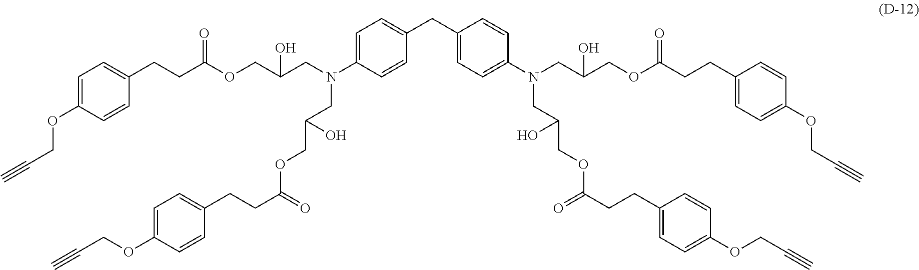 [SMILES: C#CCOc1ccc(CCC(=O)OCC(O)CN(CC(O)COC(=O)CCc2ccc(OCC#C)cc2)c2ccc(Cc3ccc(N(CC(O)COC(=O)CCc4ccc(OCC#C)cc4)CC(O)COC(=O)CCc4ccc(OCC#C)cc4)cc3)cc2)cc1]

D-13: Compound represented by formula (D-13)

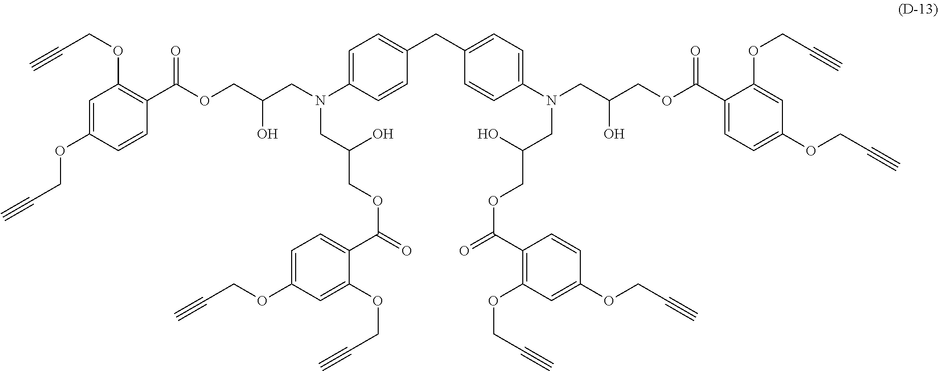 [SMILES: C#CCOc1ccc(C(=O)OCC(O)CN(CC(O)COC(=O)c2ccc(OCC#C)cc2OCC#C)c2ccc(Cc3ccc(N(CC(O)COC(=O)c4ccc(OCC#C)cc4OCC#C)CC(O)COC(=O)c4ccc(OCC#C)cc4OCC#C)cc3)cc2)c(OCC#C)c1]

D-14: Compound represented by formula (D-14)

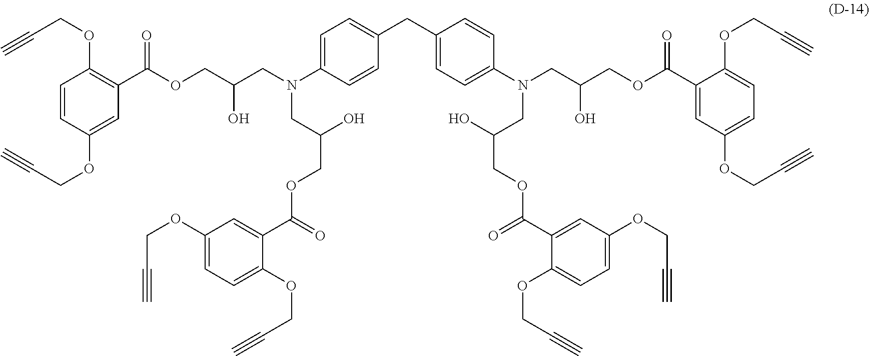 [SMILES: C#CCOc1ccc(OCC#C)c(C(=O)OCC(O)CN(CC(O)COC(=O)c2cc(OCC#C)ccc2OCC#C)c2ccc(Cc3ccc(N(CC(O)COC(=O)c4cc(OCC#C)ccc4OCC#C)CC(O)COC(=O)c4cc(OCC#C)ccc4OCC#C)cc3)cc2)c1]

D-15: Compound represented by formula (D-15)

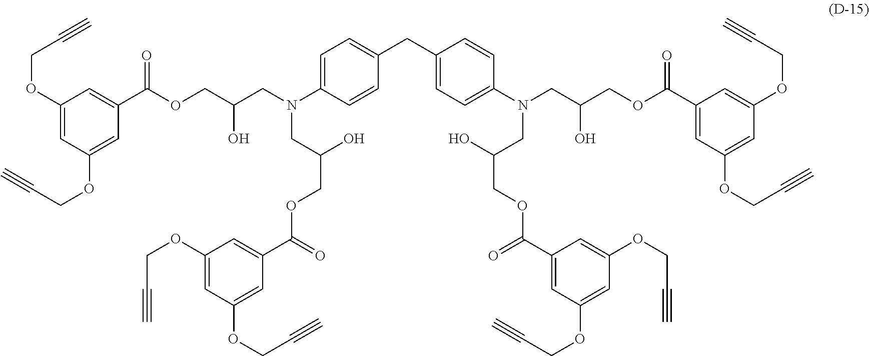 [SMILES: C#CCOc1cc(OCC#C)cc(C(=O)OCC(O)CN(CC(O)COC(=O)c2cc(OCC#C)cc(OCC#C)c2)c2ccc(Cc3ccc(N(CC(O)COC(=O)c4cc(OCC#C)cc(OCC#C)c4)CC(O)COC(=O)c4cc(OCC#C)cc(OCC#C)c4)cc3)cc2)c1]

D-16: Compound represented by formula (D-16)

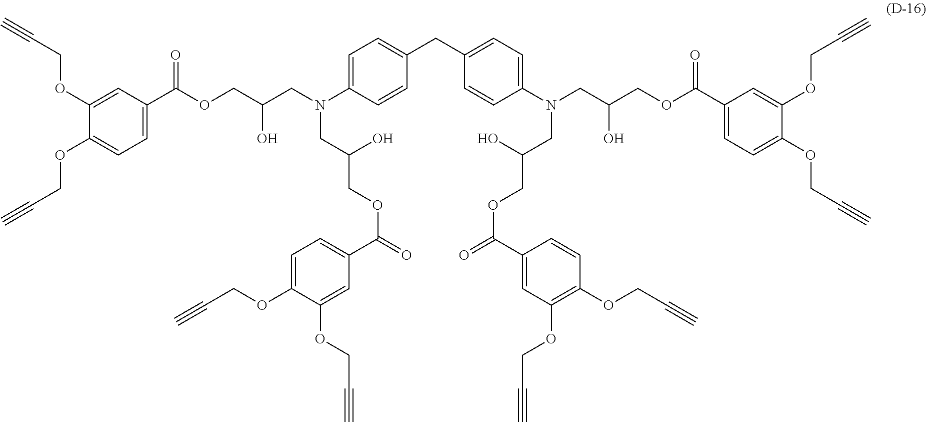 [SMILES: C#CCOc1ccc(C(=O)OCC(O)CN(CC(O)COC(=O)c2ccc(OCC#C)c(OCC#C)c2)c2ccc(Cc3ccc(N(CC(O)COC(=O)c4ccc(OCC#C)c(OCC#C)c4)CC(O)COC(=O)c4ccc(OCC#C)c(OCC#C)c4)cc3)cc2)cc1OCC#C]

### Other Polymer [E]

E-1: Polymer (Mw: 2500) having a repeating unit represented by formula (E-1)
E-2: Polymer (Mw: 3000) having a repeating unit represented by formula (E-2)
E-3: Polymer (Mw: 3500) having a repeating unit represented by formula (E-3)

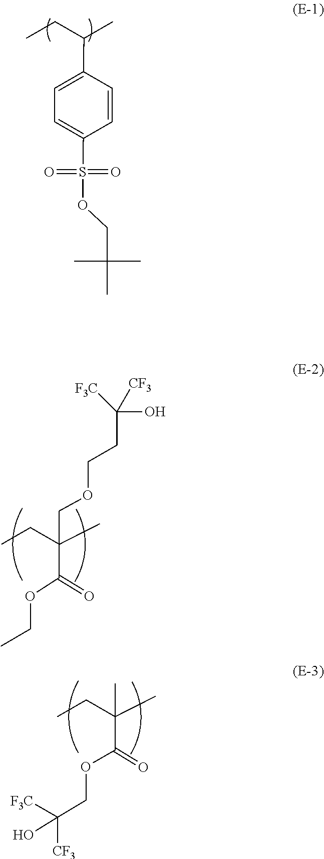

### Example 1-1

In 98 parts by mass of (B-1) as the solvent [B], 2 parts by mass of (A-1) as the compound [A] was dissolved. The resulting solution was filtered through a polytetrafluoroethylene (PTFE) membrane filter having a pore size of 0.45 μm to prepare composition (J-1).

### Examples 1-2 to 1-61 and Comparative Examples 1-1 to 1-2

Compositions (J-2) to (J-61) and (CJ-1) to (CJ-2) were prepared in the same manner as in Example 1-1 except that the components of the types and contents shown in the following Tables 2-1 and 2-2 were used. “-” in Table 2 indicates that the corresponding component was not used.

TABLE 2-1

| | | Compound [A] | | Solvent [B] | | Acid generator [C] | | Crosslinking agent [D] | | Other polymer [E] | |
|---|---|---|---|---|---|---|---|---|---|---|---|
| | | | Content | | Content | | Content | | Content | | Content |
| | Composi- | | (parts by | | (parts by | | (parts by | | (parts by | | (parts by |
| | tion | Type | mass) | Type | mass) | Type | mass) | Type | mass) | Type | mass) |
| Example 1-1 | J-1 | A-1 | 2 | B-1 | 98 | — | — | — | — | — | — |
| Example 1-2 | J-2 | A-2 | 2 | B-1 | 98 | — | — | — | — | — | — |
| Example 1-3 | J-3 | A-3 | 2 | B-1 | 98 | — | — | — | — | — | — |
| Example 1-4 | J-4 | A-4 | 2 | B-1 | 98 | — | — | — | — | — | — |
| Example 1-5 | J-5 | A-5 | 2 | B-1 | 98 | — | — | — | — | — | — |
| Example 1-6 | J-6 | A-6 | 2 | B-1 | 98 | — | — | — | — | — | — |
| Example 1-7 | J-7 | A-7 | 2 | B-1 | 98 | — | — | — | — | — | — |
| Example 1-8 | J-8 | A-8 | 2 | B-1 | 98 | — | — | — | — | — | — |
| Example 1-9 | J-9 | A-9 | 2 | B-1 | 98 | — | — | — | — | — | — |
| Example 1-10 | J-10 | A-10 | 2 | B-1 | 98 | — | — | —— | — | — | — |
| Example 1-11 | J-11 | A-11 | 2 | B-1 | 98 | — | — | — | — | — | — |
| Example 1-12 | J-12 | A-12 | 2 | B-1 | 98 | — | — | — | — | — | — |
| Example 1-13 | J-13 | A-13 | 2 | B-1 | 98 | — | — | — | — | — | — |
| Example 1-14 | J-14 | A-14 | 2 | B-1 | 98 | — | — | — | — | — | — |
| Example 1-15 | J-15 | A-15 | 2 | B-1 | 98 | — | — | — | — | — | — |
| Example 1-16 | J-16 | A-16 | 2 | B-1 | 98 | — | — | — | — | — | — |
| Example 1-17 | J-17 | A-17 | 2 | B-1 | 98 | — | — | — | — | — | — |
| Example 1-18 | J-18 | A-18 | 2 | B-1 | 98 | — | — | — | — | — | — |
| Example 1-19 | J-19 | A-19 | 2 | B-1 | 98 | — | — | — | — | — | — |
| Example 1-20 | J-20 | A-20 | 2 | B-1 | 98 | — | — | — | — | — | — |
| Example 1-21 | J-21 | A-21 | 2 | B-1 | 98 | — | — | — | — | — | — |
| Example 1-22 | J-22 | A-22 | 2 | B-1 | 98 | — | — | — | — | — | — |
| Example 1-23 | J-23 | A-23 | 2 | B-1 | 98 | — | — | — | — | — | — |
| Example 1-24 | J-24 | A-24 | 2 | B-1 | 98 | — | — | — | — | — | — |
| Example 1-25 | J-25 | A-25 | 2 | B-1 | 98 | — | — | — | — | — | — |
| Example 1-26 | J-26 | A-26 | 2 | B-1 | 98 | — | — | — | — | — | — |
| Example 1-27 | J-27 | A-27 | 2 | B-1 | 98 | — | — | — | — | — | — |
| Example 1-28 | J-28 | A-28 | 2 | B-1 | 98 | — | — | — | — | — | — |
| Example 1-29 | J-29 | A-29 | 2 | B-1 | 98 | — | — | — | — | — | — |
| Example 1-30 | J-30 | A-30 | 2 | B-1 | 98 | — | — | — | — | — | — |

TABLE 2-2

| | | Compound [A] | | Solvent [B] | | Acid generator [C] | | Crosslinking agent [D] | | Other polymer [E] | |
|---|---|---|---|---|---|---|---|---|---|---|---|
| | | | Content | | Content | | Content | | Content | | Content |
| | | | (parts by | | (parts | | (parts | | (parts by | | (parts by |
| | Composition | Type | mass) | Type | by mass) | Type | by mass) | Type | mass) | Type | mass) |
| Example 1-31 | J-31 | A-31 | 2 | B-1 | 98 | — | — | — | — | — | — |
| Example 1-32 | J-32 | A-1 | 2 | B-1 | 97 | C-1 | 0.05 | D-2 | 0.2 | E-1 | 0.2 |
| Example 1-33 | J-33 | A-1 | 2 | B-1 | 97 | C-1 | 0.05 | D-3 | 0.2 | E-2 | 0.2 |
| Example 1-34 | J-34 | A-1 | 2 | B-1 | 97 | C-1 | 0.05 | D-4 | 0.2 | E-3 | 0.2 |
| Example 1-35 | J-35 | A-1 | 2 | B-1 | 97 | C-1 | 0.05 | D-5 | 0.2 | E-2 | 0.2 |
| Example 1-36 | J-36 | A-1 | 2 | B-1 | 97 | C-1 | 0.05 | D-6 | 0.2 | E-2 | 0.2 |
| Example 1-37 | J-37 | A-1 | 2 | B-1 | 97 | C-1 | 0.05 | D-7 | 0.2 | E-2 | 0.2 |
| Example 1-38 | J-38 | A-1 | 2 | B-1 | 97 | C-1 | 0.05 | D-8 | 0.2 | E-2 | 0.2 |
| Example 1-39 | J-39 | A-1 | 2 | B-1 | 97 | C-1 | 0.05 | D-9 | 0.2 | E-2 | 0.2 |
| Example 1-40 | J-40 | A-1 | 2 | B-1 | 97 | C-1 | 0.05 | D-10 | 0.2 | E-2 | 0.2 |
| Example 1-41 | J-41 | A-1 | 2 | B-1 | 97 | C-1 | 0.05 | D-11 | 0.2 | E-2 | 0.2 |
| Example 1-42 | J-42 | A-1 | 2 | B-1 | 97 | C-1 | 0.05 | D-12 | 0.2 | E-2 | 0.2 |
| Example 1-43 | J-43 | A-1 | 2 | B-1 | 97 | C-1 | 0.05 | D-13 | 0.2 | E-2 | 0.2 |
| Example 1-44 | J-44 | A-1 | 2 | B-1 | 97 | C-1 | 0.05 | D-14 | 0.2 | E-2 | 0.2 |
| Example 1-45 | J-45 | A-1 | 2 | B-1 | 97 | C-1 | 0.05 | D-15 | 0.2 | E-2 | 0.2 |
| Example 1-46 | J-46 | A-1 | 2 | B-1 | 97 | C-1 | 0.05 | D-16 | 0.2 | E-2 | 0.2 |
| Example 1-47 | J-47 | A-16 | 2 | B-1 | 97 | C-1 | 0.05 | D-2 | 0.2 | E-2 | 0.2 |
| Example 1-48 | J-48 | A-16 | 2 | B-1 | 97 | C-1 | 0.05 | D-3 | 0.2 | E-2 | 0.2 |
| Example 1-49 | J-49 | A-16 | 2 | B-1 | 97 | C-1 | 0.05 | D-4 | 0.2 | E-2 | 0.2 |
| Example 1-50 | J-50 | A-16 | 2 | B-1 | 97 | C-1 | 0.05 | D-5 | 0.2 | E-2 | 0.2 |
| Example 1-51 | J-51 | A-16 | 2 | B-1 | 97 | C-1 | 0.05 | D-6 | 0.2 | E-2 | 0.2 |
| Example 1-52 | J-52 | A-16 | 2 | B-1 | 97 | C-1 | 0.05 | D-7 | 0.2 | E-2 | 0.2 |
| Example 1-53 | J-53 | A-1 | 2 | B-1 | 97 | C-1 | 0.05 | D-8 | 0.2 | E-2 | 0.2 |
| Example 1-54 | J-54 | A-1 | 2 | B-1 | 97 | C-1 | 0.05 | D-9 | 0.2 | E-2 | 0.2 |
| Example 1-55 | J-55 | A-1 | 2 | B-1 | 97 | C-1 | 0.05 | D-10 | 0.2 | E-2 | 0.2 |
| Example 1-56 | J-56 | A-1 | 2 | B-1 | 97 | C-1 | 0.05 | D-11 | 0.2 | E-2 | 0.2 |
| Example 1-57 | J-57 | A-1 | 2 | B-1 | 97 | C-1 | 0.05 | D-12 | 0.2 | E-2 | 0.2 |
| Example 1-58 | J-58 | A-1 | 2 | B-1 | 97 | C-1 | 0.05 | D-13 | 0.2 | E-2 | 0.2 |
| Example 1-59 | J-59 | A-1 | 2 | B-1 | 97 | C-1 | 0.05 | D-14 | 0.2 | E-2 | 0.2 |
| Example 1-60 | J-60 | A-1 | 2 | B-1 | 97 | C-1 | 0.05 | D-15 | 0.2 | E-2 | 0.2 |
| Example 1-61 | J-61 | A-1 | 2 | B-1 | 97 | C-1 | 0.05 | D-16 | 0.2 | E-2 | 0.2 |
| Comparative | CJ-1 | p-1 | 2 | B-1 | 97 | C-1 | 0.05 | D-1 | 0.2 | — | — |
| Example 1-1 | | | | | | | | | | | |
| Comparative | CJ-2 | p-5 | 2 | B-1 | 97 | C-1 | 0.05 | D-1 | 0.2 | — | — |
| Example 1-2 | | | | | | | | | | | |

### <Evaluation>

Using the compositions prepared as described above, embeddability and flatness were evaluated by the following methods. The evaluation results are shown together in the following Table 3.

### [Embeddability]

The composition was applied to a substrate with a trench pattern formed thereon having a depth of 65 nm and a width of 20 nm by spin coating using a spin coater (“LITHIUS Pro Z” available from Tokyo Electron Limited). The rotation condition of the spin coater was set such that a film-attached substrate with a film having an average thickness of 100 nm formed thereon could be obtained. Next, in the air atmosphere, the resultant was heated at 400° C. for 90 seconds and then cooled at 23° C. for 60 seconds. The sectional shape of the substrate was observed (200,000 magnifications) with a scanning electron microscope (“S-4800” manufactured by Hitachi High-Technologies Corporation), and embeddability was evaluated. The embeddability was evaluated as “A” (good) when the resist underlayer film was embedded to the bottom of the space pattern of the substrate (namely, when there was no void), and evaluated as “B” (poor) when the resist underlayer film was not embedded to the bottom of the space pattern (namely, when there was a void).

### [Flatness]

The composition prepared as described above was applied to a silicon substrate 1 with a trench pattern formed thereon having a depth of 150 nm and a width of 10 μm as illustrated in the FIGURE by spin coating using a spin coater (“CLEAN TRACK ACT12” available from Tokyo Electron Ltd.). Next, the resultant was heated at 250° C. for 60 seconds in the air atmosphere, and then cooled at 23° C. for 60 seconds to form a resist underlayer film 2 having an average thickness of 200 nm in a non-trench pattern portion, then the resultant was heated at 350° C. for 60 seconds in the air atmosphere, and then cooled at 23° C. for 60 seconds, affording a silicon substrate with a resist underlayer film. The cross-sectional shape of the silicon substrate with a resist underlayer film was observed with a scanning electron microscope (“S-4800” manufactured by Hitachi High-Technologies Corporation). The difference (AFT) between the height of the resist underlayer film 2 at the central portion b of the trench pattern and the height of the non-trench pattern portion a which is 5 μm away from the end of the trench pattern was defined as an index of flatness. When the AFT was less than 20 nm, the flatness was evaluated to be “A” (good), and when the AFT was 20 nm or more, the flatness was evaluated to be “B” (poor). The difference in height is shown in the FIGURE with exaggeration than actual one.

### <Evaluation>

Using the compositions prepared as described above, the resist pattern rectangularity due to EUV exposure was evaluated by the following method. The evaluation results are shown in the following Table 3.

### <Preparation of Resist Composition (R-1)>

The compound (S-1) to be used for the preparation of a resist composition (R-1) was synthesized by the following procedure. Into a reaction vessel, 6.5 parts by mass of isopropyltin trichloride was added while stirring 150 mL of a 0.5 N aqueous sodium hydroxide solution, and was stirred for 2 hours. The precipitate formed was collected by filtration, washed twice with 50 parts by mass of water, and then dried to obtain a compound (S-1). The compound (S-1) was an oxidized hydroxide product of a hydrolysate of isopropyltin trichloride (the oxidized hydroxide product contained i-PrSnO_{(3/2-x/2)}(OH)ₓ (0<x<3) as a structural unit).

2 parts by mass of the compound (S-1) synthesized above and 98 parts by mass of propylene glycol monoethyl ether were mixed, and the resulting mixture was subjected to removal of residual water with activated 4 Å molecular sieve, and then filtered through a filter having a pore size of 0.2 μm. Thus, resist composition (R-1) was prepared.

### [Pattern Rectangularity (EUV Exposure)]

The composition described above was applied to a 12-inch silicon wafer, heated at 220° C. for 60 seconds, and then cooled at 23° C. for 30 seconds. Thus, a resist underlayer film having an average thickness of 5 nm was formed. The resist underlayer film was coated with the resist composition (R-1) by the spin coating method using a spin coater described above, and after a lapse of a prescribed time, heated at 90° C. for 60 seconds, and then cooled at 23° C. for 30 seconds. Thus, a resist film having an average thickness of 35 nm was formed. The resist film was exposed to light using an EUV scanner (“TWINSCAN NXE:3300B”, available from ASML Co. (NA=0.3; Sigma=0.9; quadrupole illumination, with a 1:1 line and space mask having a line width of 16 nm in terms of a dimension on wafer)). After the exposure, the substrate was heated at 110° C. for 60 seconds, and subsequently cooled at 23° C. for 60 seconds. Thereafter, development was performed by a paddle method using 2-heptanone (20 to 25° C.), and then dried to obtain a substrate for evaluation with a resist pattern formed thereon. A scanning electron microscope (“CG-6300” available from Hitachi High-Tech Corporation) was used for length measurement and observation of the resist pattern of the substrate for evaluation. The pattern rectangularity was evaluated as “A” (good) when the cross-sectional shape of the pattern was rectangular, and “B” (poor) when trailing was present in the cross section of the pattern.

TABLE 3-1

| | | | | Resist pattern |
|---|---|---|---|---|
| | Composition | Embeddability | Flatness | rectangularity |
| Example 2-1 | J-1 | A | A | A |
| Example 2-2 | J-2 | A | A | A |
| Example 2-3 | J-3 | A | A | A |
| Example 2-4 | J-4 | A | A | A |
| Example 2-5 | J-5 | A | A | A |
| Example 2-6 | J-6 | A | A | A |
| Example 2-7 | J-7 | A | A | A |
| Example 2-8 | J-8 | A | A | A |
| Example 2-9 | J-9 | A | A | A |
| Example 2-10 | J-10 | A | A | A |
| Example 2-11 | J-11 | A | A | A |
| Example 2-12 | J-12 | A | A | A |
| Example 2-13 | J-13 | A | A | A |
| Example 2-14 | J-14 | A | A | A |
| Example 2-15 | J-15 | A | A | A |
| Example 2-16 | J-16 | A | A | A |
| Example 2-17 | J-17 | A | A | A |
| Example 2-18 | J-18 | A | A | A |
| Example 2-19 | J-19 | A | A | A |
| Example 2-20 | J-20 | A | A | A |
| Example 2-21 | J-21 | A | A | A |
| Example 2-22 | J-22 | A | A | A |
| Example 2-23 | J-23 | A | A | A |
| Example 2-24 | J-24 | A | A | A |
| Example 2-25 | J-25 | A | A | A |
| Example 2-26 | J-26 | A | A | A |
| Example 2-27 | J-27 | A | A | A |
| Example 2-28 | J-28 | A | A | A |
| Example 2-29 | J-29 | A | A | A |
| Example 2-30 | J-30 | A | A | A |

TABLE 3-2

| | | | | Resist pattern |
|---|---|---|---|---|
| | Composition | Embeddability | Flatness | rectangularity |
| Example 2-31 | J-31 | A | A | A |
| Example 2-32 | J-32 | A | A | A |
| Example 2-33 | J-33 | A | A | A |
| Example 2-34 | J-34 | A | A | A |
| Example 2-35 | J-35 | A | A | A |
| Example 2-36 | J-36 | A | A | A |
| Example 2-37 | J-37 | A | A | A |
| Example 2-38 | J-38 | A | A | A |
| Example 2-39 | J-39 | A | A | A |
| Example 2-40 | J-40 | A | A | A |
| Example 2-41 | J-41 | A | A | A |
| Example 2-42 | J-42 | A | A | A |
| Example 2-43 | J-43 | A | A | A |
| Example 2-44 | J-44 | A | A | A |
| Example 2-45 | J-45 | A | A | A |
| Example 2-46 | J-46 | A | A | A |
| Example 2-47 | J-47 | A | A | A |
| Example 2-48 | J-48 | A | A | A |
| Example 2-49 | J-49 | A | A | A |
| Example 2-50 | J-50 | A | A | A |
| Example 2-51 | J-51 | A | A | A |
| Example 2-52 | J-52 | A | A | A |
| Example 2-53 | J-53 | A | A | A |
| Example 2-54 | J-54 | A | A | A |
| Example 2-55 | J-55 | A | A | A |
| Example 2-56 | J-56 | A | A | A |
| Example 2-57 | J-57 | A | A | A |
| Example 2-58 | J-58 | A | A | A |
| Example 2-59 | J-59 | A | A | A |
| Example 2-60 | J-60 | A | A | A |
| Example 2-61 | J-61 | A | A | A |
| Comparative | CJ-1 | B | B | B |
| Example 2-1 | | | | |
| Comparative | CJ-2 | B | B | B |
| Example 2-2 | | | | |

As can be seen from the results in Tables 3-1 and 3-2, the compositions of Examples and the resist underlayer films formed from the compositions were excellent in pattern rectangularity to Comparative Example. Furthermore, the compositions of Examples and the resist underlayer films formed from the compositions were excellent also in embeddability and flatness to Comparative Examples.

According to the method for manufacturing a semiconductor substrate of the present disclosure, since a resist underlayer film excellent in pattern rectangularity is formed, a well patterned semiconductor substrate can be obtained. According to the composition for forming a resist underlayer film of the present disclosure, it is possible to form a resist underlayer film excellent in pattern rectangularity. Furthermore, according to the method for manufacturing a semiconductor substrate of the present disclosure, it is possible to form a resist underlayer film excellent in embeddability with which a pattern of a substrate can be sufficiently embedded and also in flatness of the film after the pattern is embedded. The composition for forming a resist underlayer film of the present disclosure can form a resist underlayer film excellent also in embeddability and flatness. Therefore, they can suitably be used for, for example, manufacturing semiconductor devices expected to be further microfabricated in the future.

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A method for manufacturing a semiconductor substrate, the method comprising:
applying a resist underlayer film forming composition directly or indirectly to a substrate to form a resist underlayer film;
applying a composition for forming a resist film directly or indirectly to the resist underlayer film to form a resist film;
exposing the resist film to light; and
developing the exposed resist film,
wherein
the resist underlayer film forming composition comprises:
a compound; and
a solvent,
wherein
the compound comprises a plurality of groups each represented by —OR^{A}, wherein each R^{A} is independently a hydrogen atom, a monovalent heteroatom-containing group having 1 to 10 carbon atoms, or a monovalent organic group having 1 to 10 carbon atoms other than the monovalent heteroatom-containing group having 1 to 10 carbon atoms, wherein in the plurality of R^{A}'s, when a proportion of hydrogen atoms is denoted by x, a proportion of monovalent heteroatom-containing groups having 1 to 10 carbon atoms is denoted by y, and a proportion of monovalent organic groups having 1 to 10 carbon atoms is denoted by z, the compound satisfies relationships of x+y+z=100, 20≤x≤95, and 5≤y≤80, and
the compound is a polymer comprising a repeating unit represented by formula (1), an aromatic ring-containing compound that has a molecular weight of 750 or more and 3000 or less and comprises —OR^{A}, or a combination thereof: 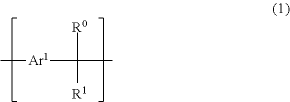
wherein in the formula (1), Ar¹ is a divalent group comprising an aromatic ring having 5 to 40 ring members; R⁰ is a hydrogen atom or a monovalent organic group having 1 to 40 carbon atoms; R¹ is a monovalent organic group having 1 to 40 carbon atoms; at least one selected from the group consisting of Ar¹, R⁰ and R¹ comprises —OR^{A}.

2. The method according to claim 1, wherein the heteroatom-containing group comprises at least one selected from the group consisting of —O—, —CO—, —S—, —SO₂—, —NR′—, —NO₂, and —CN, wherein R′ is a monovalent organic group.

3. The method according to claim 1, wherein the heteroatom-containing group comprises at least one oxygen atom.

4. The method according to claim 1, wherein the aromatic ring is at least one aromatic hydrocarbon ring selected from the group consisting of a benzene ring, a naphthalene ring, an anthracene ring, a phenalene ring, a phenanthrene ring, a pyrene ring, a fluorene ring, and a perylene ring.

5. The method according to claim 1, wherein the substrate has a pattern.

6. The method according to claim 1, wherein the resist film comprises a metal.

7. A resist underlayer film forming composition comprising:
a compound; and
a solvent,
wherein
the compound comprises a plurality of groups each represented by —OR^{A}, wherein each R^{A} is independently a hydrogen atom, a monovalent heteroatom-containing group having 1 to 10 carbon atoms, or a monovalent organic group having 1 to 10 carbon atoms other than the monovalent heteroatom-containing group having 1 to 10 carbon atoms, wherein in the plurality of R^{A}'s, when a proportion of hydrogen atoms is denoted by x, a proportion of monovalent heteroatom-containing groups having 1 to 10 carbon atoms is denoted by y, and a proportion of monovalent organic groups having 1 to 10 carbon atoms is denoted by z, the compound satisfies relationships of x+y+z=100, 20≤x≤95, and 5≤y≤80, and
the compound is a polymer comprising a repeating unit represented by formula (1), an aromatic ring-containing compound that has a molecular weight of 750 or more and 3000 or less and comprises —OR^{A}, or a combination thereof: 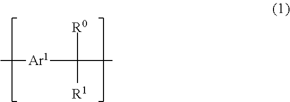
wherein in the formula (1), Ar¹ is a divalent group comprising an aromatic ring having 5 to 40 ring members; R⁰ is a hydrogen atom or a monovalent organic group having 1 to 40 carbon atoms; R¹ is a monovalent organic group having 1 to 40 carbon atoms; at least one selected from the group consisting of Ar¹, R⁰ and R¹ comprises —OR^{A}.

8. The resist underlayer film forming composition according to claim 7, wherein the heteroatom-containing group comprises at least one selected from the group consisting of —O—, —CO—, —S—, —SO₂—, —NR′—, —NO₂, and —CN, wherein R′ is a monovalent organic group.

9. The resist underlayer film forming composition according to claim 7, wherein the heteroatom-containing group comprises at least one oxygen atom.

10. The resist underlayer film forming composition according to claim 7, wherein the aromatic ring is at least one aromatic hydrocarbon ring selected from the group consisting of a benzene ring, a naphthalene ring, an anthracene ring, a phenalene ring, a phenanthrene ring, a pyrene ring, a fluorene ring, and a perylene ring.

11. The resist underlayer film forming composition according to claim 7, wherein the composition is suitable for embedding a pattern of a substrate.

12. The resist underlayer film forming composition according to claim 7, wherein the composition is suitable for forming an underlayer film of a metal-containing resist film.
